(19) United States
(12) Patent Application Publication
(10) Pub. No.: US 2025/0038081 A1
(43) Pub. Date: Jan. 30, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Jongho PARK, Suwon-si (KR); Unbyoung KANG, Suwon-si (KR); Seonghoon BAE, Suwon-si (KR); Jaemok JUNG, Suwon-si (KR); Juil CHOI, Suwon-si (KR); Taeoh HA, Suwon-si (KR)

(73) Assignee: Samsung Electronics Co., Ltd., Suwon-si (KR)

(21) Appl. No.: 18/734,529

(22) Filed: Jun. 5, 2024

(30) Foreign Application Priority Data
Jul. 26, 2023 (KR) 10-2023-0097266

(51) Int. Cl. H01L 23/498; H01L 23/00; H01L 23/31; H01L 23/36

(52) U.S. Cl. CPC H01L 23/49811; H01L 23/3107; H01L 23/36; H01L 23/49822; H01L 24/24; H01L 23/49816; H01L 24/16; H01L 24/32; H01L 24/73; H01L 2224/16227; H01L 2224/2401; H01L 2224/32225; H01L 2224/73204

(57) ABSTRACT

A semiconductor package includes a lower redistribution wiring layer having a first region and a second region and including first redistribution wirings, a semiconductor chip disposed on the first region of the lower redistribution wiring layer, a molding member covering the semiconductor chip on the lower redistribution wiring layer, a plurality of vertical conductive structures penetrating the molding member on the second region of the lower redistribution wiring layer, electrically connected to the first redistribution wirings, and including first conductive pillars and second conductive pillars stacked on the first conductive pillars respectively, and an upper redistribution wiring layer disposed on the molding member and having second redistribution wirings electrically connected to the plurality of vertical conductive structures. Each of the first conductive pillars has a first length and each of the second conductive pillars has a second length greater than the first length.

### PRIORITY STATEMENT

This application claims priority under 35 U.S.C. § 119 to Korean Patent Application No. 10-2023-0097266, filed on Jul. 26, 2023, in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a fan out package and a method of manufacturing the same.

### 2. Description of the Related Art

In manufacturing a fan-out package, a molding member may be formed on a lower redistribution wiring layer to cover copper posts and a semiconductor chip. The copper posts may be formed by forming a photosensitive insulating material such as a photoresist pattern, on the lower redistribution wiring layer and filling openings of the photoresist pattern with a conductive material. A thickness of the semiconductor chip may be increased in order to improve heat dissipation performance of the package, but it may be difficult to increase the thickness of the semiconductor chip due to limitations in the photo process and plating process using the photoresist pattern.

### SUMMARY

Example embodiments provide a semiconductor package including vertical conductive structures that have improved heat dissipation properties and can reduce processing steps.

Example embodiments provide a method of manufacturing the semiconductor package.

According to some example embodiments, a semiconductor package includes a lower redistribution wiring layer having a first region and a second region, and including first redistribution wirings; a semiconductor chip on the first region of the lower redistribution wiring layer and electrically connected to the first redistribution wirings; a molding member covering the semiconductor chip on the lower redistribution wiring layer; a plurality of vertical conductive structures penetrating the molding member on the second region of the lower redistribution wiring layer, each of the plurality of vertical conductive structures including a first conductive pillar on a bonding pad on the first redistribution wiring in the second region and a second conductive pillar stacked on the first conductive pillar; and an upper redistribution wiring layer on the molding member and having second redistribution wirings electrically connected to the plurality of vertical conductive structures. The second redistribution wirings include a first upper redistribution wiring extending from an end portion of the second conductive pillar on an upper molding member, and a second upper redistribution wiring stacked on the first upper redistribution wiring.

According to some example embodiments, a semiconductor package includes a lower redistribution wiring layer having a first region and a second region surrounding the first region, the lower redistribution wiring layer including first redistribution wirings; a plurality of first and second bonding pads on an uppermost redistribution wirings of the first redistribution wirings on an upper surface of the lower redistribution wiring layer, the plurality of first bonding pads arranged in the first region, the plurality of second bonding pads arranged in the second region; a semiconductor chip mounted on the first region of the lower redistribution wiring layer, on the lower redistribution wiring layer such that a front surface on which chip pads are arranged faces the lower redistribution wiring layer, and electrically connected to the first redistribution wirings; a molding member covering the semiconductor chip on the lower redistribution wiring layer; a plurality of vertical conductive structures penetrating the molding member on the second region of the lower redistribution wiring layer, the plurality of vertical conductive structure including first conductive pillars on the plurality of second bonding pads and second conductive pillars stacked on the first conductive pillars respectively; and an upper redistribution wiring layer on the molding member, having second redistribution wirings electrically connected to the plurality of vertical conductive structures and a heat dissipation pattern on a backside surface of the semiconductor chip.

According to some example embodiments, a semiconductor package includes a lower redistribution wiring layer having a first region and a second region surrounding the first region, the lower redistribution wiring layer including first redistribution wirings; a semiconductor chip on the first region of the lower redistribution wiring layer and arranged on the lower redistribution wiring layer such that a front surface on which chip pads are arranged faces the lower redistribution wiring layer; a molding member covering the semiconductor chip on the lower redistribution wiring layer; a plurality of vertical conductive structures penetrating the molding member on the second region of the lower redistribution wiring layer, the plurality of vertical conductive structures electrically connected to the first redistribution wirings, each of the plurality of vertical conductive structures including a first conductive pillar and a second conductive pillar stacked on the first conductive pillar; and an upper redistribution wiring layer on the molding member, having second redistribution wirings electrically connected to the plurality of vertical conductive structures and a heat dissipation pattern on a backside surface of the semiconductor chip. Each of the first conductive pillars has a first length and each of the second conductive pillars has a second length greater than the first length.

According to some example embodiments, in a method of manufacturing a semiconductor package, a lower redistribution wiring layer having a first region and a second region is formed, the lower redistribution wiring layer including first redistribution wirings. A plurality of first bonding pads and a plurality of second bonding pads are formed on uppermost redistribution wirings on an upper surface of the lower redistribution wiring layer, the plurality of first bonding pads in the first region, the plurality of second bonding pads in the second region. A plurality of first conductive pillars are formed on the plurality of second bonding pads, respectively. A semiconductor chip is mounted on the first region of the lower redistribution wiring layer to be electrically connected to the first redistribution wirings. A molding member is formed on the lower redistribution wiring layer covering the semiconductor chip and the plurality of first conductive pillars. Second conductive pillars that penetrate the molding member and are stacked on the first conductive pillars are formed. An upper redistribution wiring layer is formed on an upper surface of the molding member, the upper redistribution wiring layer having second redistribution wirings that are electrically connected to the second conductive pillars.

### BRIEF DESCRIPTION OF THE DRAWINGS

Various example embodiments will be more clearly understood from the following detailed description taken in conjunction with the accompanying drawings. FIGS. 1 to 33 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating first upper redistribution wirings and a heat dissipation pattern provided on an upper surface of a molding member of FIG. 1.

FIGS. 4 to 21 are views illustrating a method of manufacturing a semiconductor package in accordance with example embodiments.

FIG. 22 is a cross-sectional view illustrating a semiconductor package in accordance with example embodiments.

FIG. 23 is an enlarged cross-sectional views illustrating portion ‘I’ in FIG. 22.

FIGS. 24 to 30 are cross-sectional views illustrating a method of manufacturing a semiconductor package in accordance with example embodiments.

FIG. 31 is a cross-sectional view illustrating a semiconductor package in accordance with example embodiments.

FIG. 32 is a cross-sectional view illustrating a semiconductor package in accordance with example embodiments.

FIG. 33 is a cross-sectional view illustrating a semiconductor package in accordance with example embodiments.

### DETAILED DESCRIPTION

Hereinafter, various example embodiments will be explained in detail with reference to the accompanying drawings.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

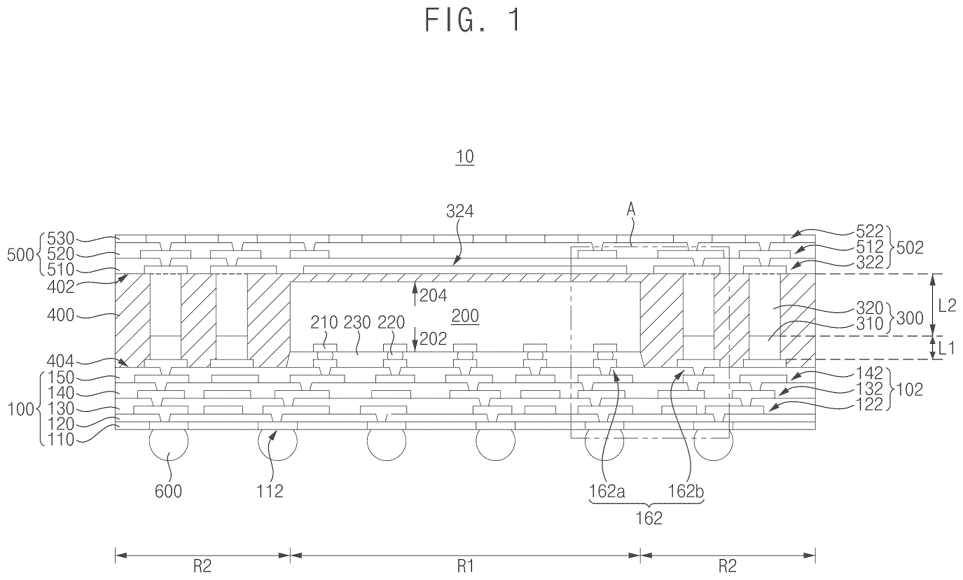

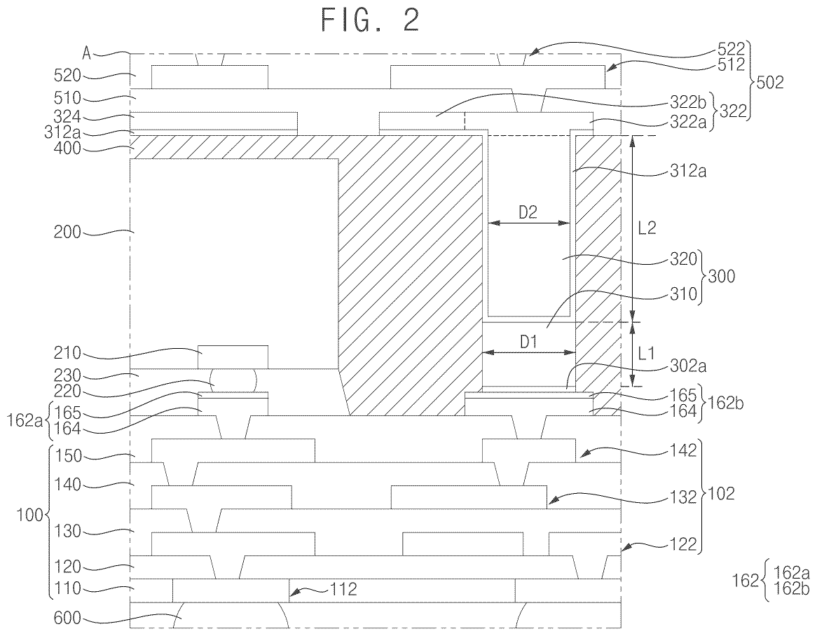

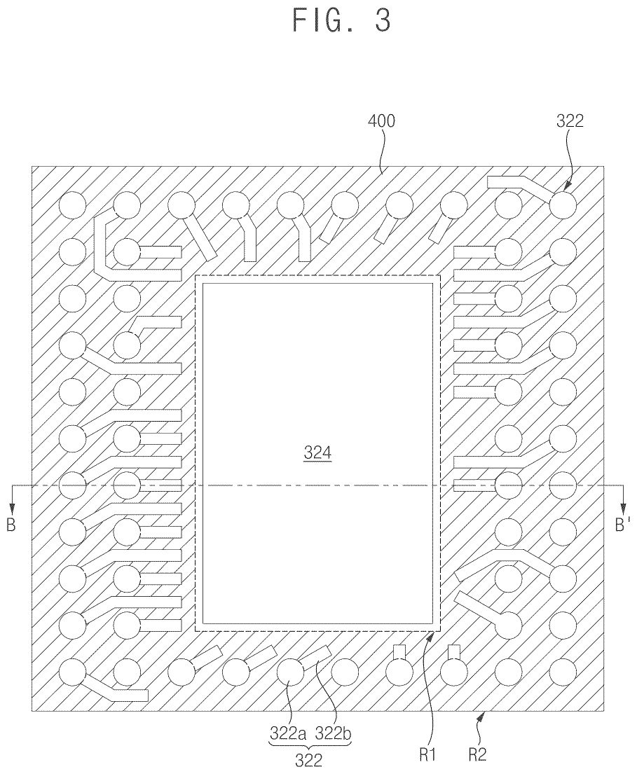

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating first upper redistribution wirings and a heat dissipation pattern provided on an upper surface of a molding member of FIG. 1. FIG. 1 includes a cross section taken along the line B-B′ in FIG. 3.

Referring to FIGS. 1 to 3, a semiconductor package 10 may include a lower redistribution wiring layer 100, a semiconductor chip 200 disposed on the lower redistribution wiring layer 100, a molding member 400 on an upper surface of the lower redistribution wiring layer 100 and covering at least a portion of the semiconductor chip 200, an upper redistribution wiring layer 500 disposed on an upper surface 302 of the molding member 400, and a plurality of vertical conductive structures 300 penetrating the molding member 400 and electrically connecting the lower redistribution wiring layer 100 and the upper redistribution wiring layer 500. In addition, the semiconductor package 10 may further include external connection members 600 disposed on an outer surface of the lower redistribution wiring layer 100.

In some example embodiments, the semiconductor package 10 may be a fan out package in which the lower redistribution wiring layer 100 extends to a lower surface of the molding member 400 to cover an outer side surface of the semiconductor chip 200. The lower redistribution wiring layer 100 may be formed by a wafer level redistribution wiring process. Additionally, the semiconductor package 10 may be provided as a unit package on which a second package is stacked.

Additionally, the semiconductor package 10 may be provided as a System In Package (SIP). For example, one or more semiconductor chips may be disposed on the lower redistribution wiring layer 100. The semiconductor chips may include a logic chip including a logic circuit and/or a memory chip. The logic chip may be a controller that controls memory chips. The memory chip includes various types of memory circuits such as DRAM, SRAM, flash, PRAM, ReRAM, FeRAM, or MRAM.

In some example embodiments, the lower redistribution wiring layer 100 may have first redistribution wirings 102. The semiconductor chip 200 may be disposed on the lower redistribution wiring layer 100 to be electrically connected to the first redistribution wirings 102. The lower redistribution wiring layer 100 may be provided on a front surface 202 of the semiconductor chip 200 to serve as a front redistribution wiring layer. Accordingly, the lower redistribution wiring layer 100 may be a front redistribution wiring layer (FRDL) of the fan out package.

For example, the lower redistribution wiring layer 100 may include a plurality of first, second, third, fourth and fifth lower insulating layers 110, 120, 130, 140 and 150 and the first redistribution wirings 102 provided in the first, second, third, fourth and fifth lower insulating layers. The first redistribution wirings 102 may include first, second and third lower redistribution wirings 122, 132 and 142.

The first, second, third, fourth and fifth lower insulating layers may include a polymer or a dielectric layer. For example, the first, second, third, fourth and fifth lower insulating layers may include a photosensitive insulating layer such as photo imagable dielectric (PID). The first, second, third, fourth and fifth lower insulating layers may be formed by a vapor deposition process, a spin coating process, etc. The first redistribution wirings may include aluminum (Al), copper (Cu), tin (Sn), nickel (Ni), gold (Au), platinum (Pt), or an alloy thereof. The first redistribution wiring may be formed by a plating process, an electroless plating process, a vapor deposition process, etc.

For example, a lower bonding pad 112 may be provided in the first lower insulating layer 110. The lower bonding pad 112 may be a bump pad. The bump pad may include a solder pad or pillar pad. For example, the lower bonding pad may include copper (Cu), aluminum (Al), tin (Sn), nickel (Ni), gold (Au), platinum (Pt), or an alloy thereof.

The second lower insulating layer 120 may be formed on the first lower insulating layer 110 and the first lower redistribution wiring 122 may be formed on the second lower insulating layer 120. The first lower redistribution wiring 122 may be electrically connected to the lower bonding pad through a first opening formed in the second lower insulating layer 120.

The third lower insulating layer 130 may be formed on the second lower insulating layer 120 and the second lower redistribution wiring 132 may be formed on the third lower insulating layer 130. The second lower redistribution wiring 132 may be electrically connected to the first lower redistribution wiring 122 through a second opening formed in the third lower insulating layer 130.

The fourth lower insulating layer 140 may be formed on the third lower insulating layer 130 and the third lower redistribution wiring 142 may be formed on the fourth lower insulating layer 140. The third lower redistribution wiring 142 may be electrically connected to the second lower redistribution wiring 132 through a third opening formed in the fourth lower insulating layer 140.

A solder resist layer 150 as the fifth lower insulating layer may be formed on the fourth lower insulating layer 140 and may expose at least portions of the third lower redistribution wirings 142. Upper bonding pads 162 such as UBM may be disposed on the exposed portions of the third lower redistribution wirings 142 as the uppermost redistribution wirings. The solder resist layer 150 may function as a passivation layer.

The numbers and arrangements of the lower insulating layers and the lower redistribution wirings of the lower redistribution wiring layer are provided as examples, and it will be appreciated that the present inventive concepts are not limited thereto.

In some example embodiments, when viewed in plan view, the lower redistribution wiring layer 100 may include the first region R1 as a chip mounting region overlapping with a semiconductor chip to be mounted on the lower redistribution wiring layer 100 as will be described later, and the second region R2 as a connector region surrounding the first region R1 and. The second region R2 may be a fan-out region outside the region where the semiconductor chip is disposed.

The upper bonding pads 162 may be exposed from an upper surface of the lower redistribution wiring layer 100. The upper bonding pads 162 may include first bonding pads 162a as chip connection bonding pads formed on the uppermost first redistribution wirings 142 located in the first region R1, and second bonding pads 162b as conductive structure connection bonding pads formed on the uppermost first redistribution wirings 142 located in the second region R2.

For example, the upper bonding pads 162 may have a multilayer structure. The upper bonding pad 162 may include a bonding pad pattern 164 and a plating pad pattern 165 formed on the bonding pad pattern 164. The bonding pad pattern 164 may include copper (Cu), and the plating pad pattern 165 may include nickel (Ni), gold (Au), or titanium (Ti).

In some example embodiments, the semiconductor chip 200 may have a plurality of chip pads 210 on a first surface 202, for example, an active surface thereof. The semiconductor chip 200 may be mounted on the lower redistribution wiring layer 100 such that the first surface on which the chip pads 210 are formed faces the lower redistribution wiring layer 100.

The semiconductor chip 200 may be mounted on the lower redistribution wiring layer 200 by a flip chip bonding method. The semiconductor chip 200 may be mounted on the lower redistribution wiring layer 100 via conductive bumps 220. The conductive bump 220 may be disposed between the bonding pad 152 on the fourth lower redistribution wiring 142 of the lower redistribution wiring layer 100 and the chip pad 210 of the semiconductor chip 200 to electrically connect the semiconductor chip 200 and the first redistribution wiring 102. For example, the conductive bump 220 may include a pillar bump formed on the chip pad 210 of the semiconductor chip 200 and a solder bump formed on the pillar bump. Alternatively, the conductive bump 220 may include a solder bumps formed on the chip pad 210 of the semiconductor chip 200. An underfill member 230 may be disposed between the semiconductor chip 200 and the lower redistribution wiring layer 100.

The semiconductor chip may be a logic chip including a logic circuit. The logic chip may be a controller that controls memory chips. The semiconductor chip may be a processor chip such as an ASIC or an application processor (AP) serving as a host such as a CPU, GPU, or SOC.

Although only a few chip pads are illustrated in the figures, the structures and arrangements of the chip pads are provided as examples, and it will be understood that the present inventive concepts are not limited thereto. Additionally, although only one semiconductor chip is illustrated, it may not be limited thereto, and a plurality of semiconductor chips may be stacked on the lower redistribution wiring layer.

In some example embodiments, the molding member 400 may cover at least a portion of the semiconductor chip 200 on the upper surface of the lower redistribution wiring layer 100. The molding member 400 may include a first molding portion covering an upper surface 204 of the semiconductor chip 200 and a second sealing portion covering the upper surface of the lower redistribution wiring layer 100 around the semiconductor chip 200.

For example, the molding member 400 may include an epoxy mold compound (EMC). The molding member 400 may be formed by a molding process, a screen printing process, a lamination process, etc.

In some example embodiments, a plurality of vertical conductive structures 300 may extend in a vertical direction to penetrate the molding member 400. The vertical conductive structure 300 may be formed on the second bonding pad 162b on the uppermost first redistribution wiring 142 located in the second region R2.

The vertical conductive structure 300 may be provided to penetrate the molding member 400 and may serve as an electrical connection path. The vertical conductive structure 300 may be a through mold via (TMV) formed to extend through the second sealing portion of the molding member 400. For example, the vertical conductive structures 300 may be provided a fan-out region R2 outside an area where the semiconductor chip 200 is disposed, to electrically connect the lower redistribution wiring layer 100 and the upper redistribution wiring layer 500.

As illustrated in FIG. 2, the vertical conductive structure 300 may include a first conductive pillar 310 on the second bonding pad 162b and a second conductive pillar 320 stacked on the first conductive pillar 310.

The first conductive pillars 310 may extend upward from the second bonding pads 162b on the first redistribution wirings 102 of the first redistribution wiring layer 100, for example, the third uppermost redistribution wirings 142.

For example, a first diameter D1 of the first conductive pillar 310 may be in a range of 50 μm to 200 μm, and a first length L1 of the first conductive pillar 310 may be in a range of 50 μm to 100 μm. A second diameter D2 of the second conductive pillar 320 may be within a range of 30 μm to 180 μm, and a second length L2 of the second conductive pillar 320 may be within a range of 200 μm to 300 μm. The length L2 of the second conductive pillar 320 may be at least twice the length L1 of the first conductive pillar 310.

The first conductive pillars 310 may be formed by forming a photosensitive insulating material such as a photoresist pattern on the upper surface of the lower redistribution wiring layer 100 and filling openings of the photoresist pattern that expose the second bonding pads 162b with a conductive material. The second conductive pillars 320 may be formed by forming the molding member 400 that covers the first conductive pillars 310 and the semiconductor chip 200, performing a laser drilling process on an upper surface 402 of the molding member 400 to form recesses that expose the upper surfaces of the first conductive pillars 310, and filling the recesses with a conductive material. Since the vertical conductive structure 300 includes the first and second conductive pillars 310 and 320 sequentially formed by two first and second plating processes, a length of the vertical conductive structure 300 may be increased.

In some example embodiments, a first upper redistribution wiring 322 may be provided on an upper end portion of the second conductive pillar 320. The first upper redistribution wiring 322 may include a redistribution pad 322a provided on the upper end portion of the second conductive pillar 320 and a redistribution line 322b extending from the redistribution pad 322a on an upper surface 402 of the molding member 400. A heat dissipation pattern 324 may extend on the upper surface 402 of the molding member 400 to cover at least a portion of the backside surface 204 of the semiconductor chip 200. An upper surface of the first upper redistribution wiring 322 may be located on the same plane as an upper surface of the heat dissipation pattern 324. The first upper redistribution wiring 322 may be used as a first-stage (e.g., lowermost) upper redistribution wiring of the upper redistribution wiring layer 500. The second conductive pillar 320, the first upper redistribution wiring 322 and the heat dissipation pattern 324 may be formed together by the same plating process. The second conductive pillar 320, the first upper redistribution 322 and the heat dissipation pattern 324 may include the same metal material. Examples of the metal material include copper (Cu), aluminum (Al), tin (Sn), nickel (Ni), gold (Au), platinum (Pt), or an alloy thereof.

In some example embodiments, the upper redistribution wiring layer 500 may be disposed on the molding member 400 and may include second redistribution wirings 402 electrically connected to the vertical conductive structure 300 respectively. The second redistribution wirings 502 may include upper redistribution wirings 322, 512, 522 stacked in at least two layers. The second redistribution wirings 502 may be provided on the molding member 400 to serve as backside redistribution wirings. Accordingly, in some example embodiments, the upper redistribution wiring layer 500 may be a backside redistribution wiring layer (BRDL) of the fan out package.

The second redistribution wirings 502 may include the first upper redistribution wirings 322, the second upper redistribution wiring 512 and the third upper redistribution wiring 522 sequentially stacked. For example, the first upper redistribution wiring 322 may correspond to a lowermost redistribution wiring among the second redistribution wirings, and the third upper redistribution wiring 522 may correspond to an uppermost redistribution wiring among the second redistribution wirings.

A first upper insulating layer 510 may be provided on the upper surface 402 of the molding member 400 and may have openings that expose upper portions of the vertical conductive structures 300, for example, the first upper redistribution wirings 322. The second upper redistribution wirings 512 may be formed on the first upper insulating layer 510 and may be electrically connected to the upper portions of the vertical conductive structures 300, for example, the first upper redistribution wirings 322, through the openings of the first upper insulating layer 510.

A second upper insulating layer 520 may be provided on the first upper insulating layer 510 and may have openings that expose the second upper redistribution wirings 512. The third upper redistribution wirings 522 may be formed on the second upper insulating layer 520 and at least portion of the third upper redistribution wirings 522 may be electrically connected to the second upper redistribution wirings 512 through the openings of the second upper insulating layer 520.

Although not illustrated in the figures, upper bonding pads may be provided on the third upper redistribution wirings 522, respectively. The third upper insulating layer 530 may be provided on the second upper insulating layer 520 and may expose at least portions of the upper bonding pads. The third upper insulating layer 530 may function as a passivation layer.

For example, the first, second and third upper insulating layers may include a polymer, a dielectric layer, etc. The first, second and third insulating layers may include a photosensitive insulating material such as PID or an insulating film such as ABF. The second redistribution wirings may include copper (Cu), aluminum (Al), tin (Sn), nickel (Ni), gold (Au), platinum (Pt), or an alloy thereof.

It will be understood that the number, size, and arrangement of the upper insulating layers and the upper redistribution wirings of the second redistribution wiring layer are provided as examples, and the present inventive concepts are not limited thereto.

In some example embodiments, the external connection members 600 may be disposed on the lower bonding pads 112 on an outer surface of the lower redistribution wiring layer 100. For example, the external connection member 600 may include a solder ball. The solder ball may have a diameter of 300 μm to 500 μm. The semiconductor package 10 may be mounted on a module substrate (not illustrated) via the solder balls to form a memory module.

As mentioned above, the semiconductor package 10 as the fan-out wafer level package may include the lower redistribution wiring layer 100, the semiconductor chip 200 disposed on the lower redistribution wiring layer 100, the molding member 400 covering the at least a portion of the semiconductor chip 200 on the upper surface of the lower redistribution wiring layer 100, the plurality of vertical conductive structures 300 penetrating the molding member 400, and the upper redistribution wiring layer 500 disposed on the upper surface 402 of the molding member 400.

Since the vertical conductive structure 300 includes the first conductive pillar 310 formed by the first plating process and the second conductive pillar 320 formed by the second plating process after the first plating process, the length of the vertical conductive structure 300 may be increased. Thus, the semiconductor chip 200 having a relatively greater thickness may be applied to thereby improve heat dissipation characteristics of the semiconductor chip 200.

Additionally, since the first upper redistribution wiring 322 and the heat dissipation pattern 324 are simultaneously formed when forming the second conductive pillar 320, process steps may be reduced and heat dissipation performance of the semiconductor package may be improved.

Hereinafter, a method of manufacturing the semiconductor package of FIG. 1 will be described.

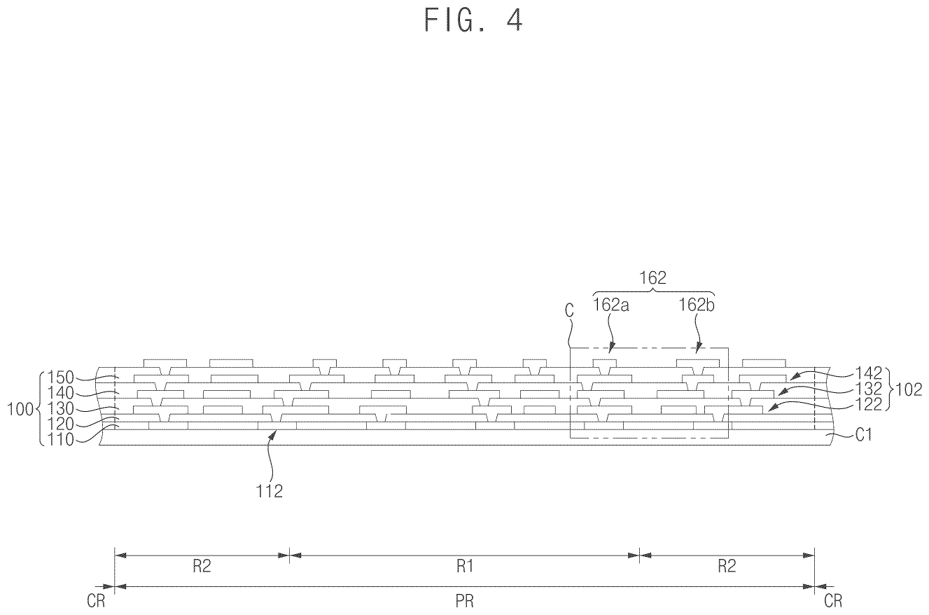

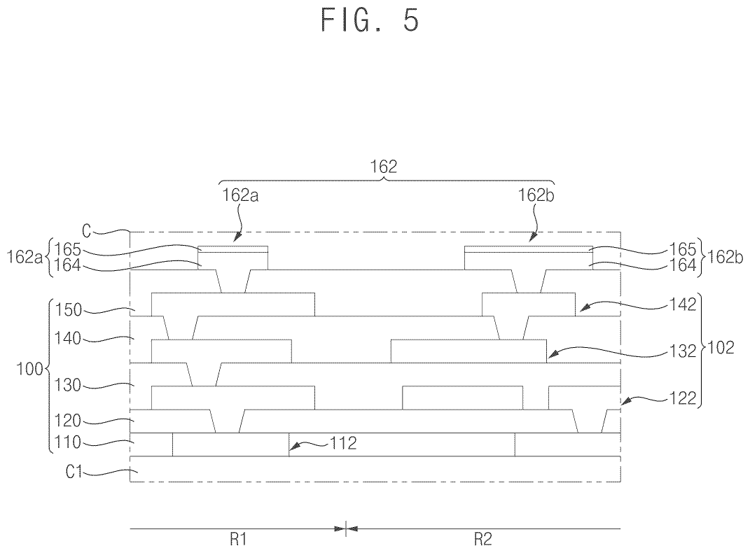

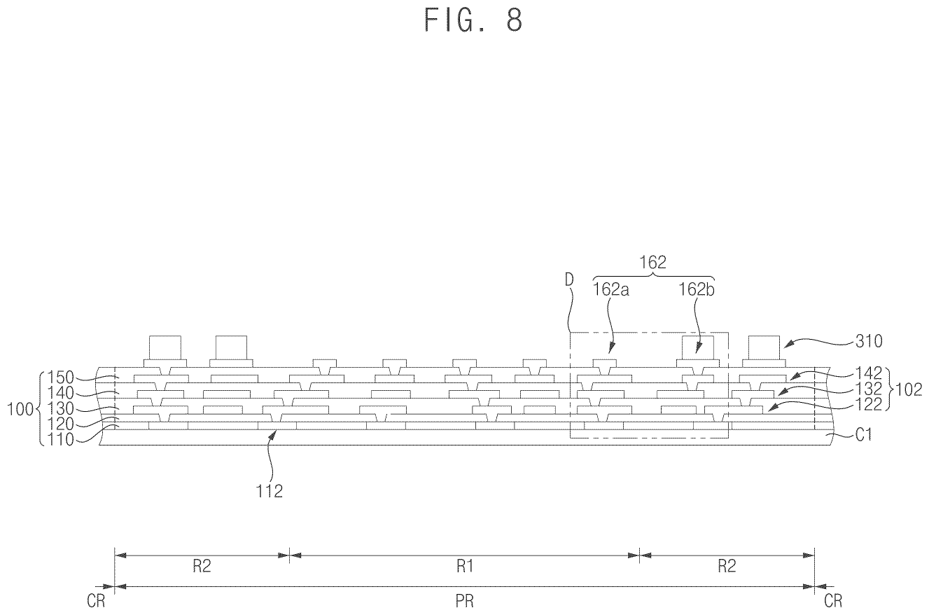

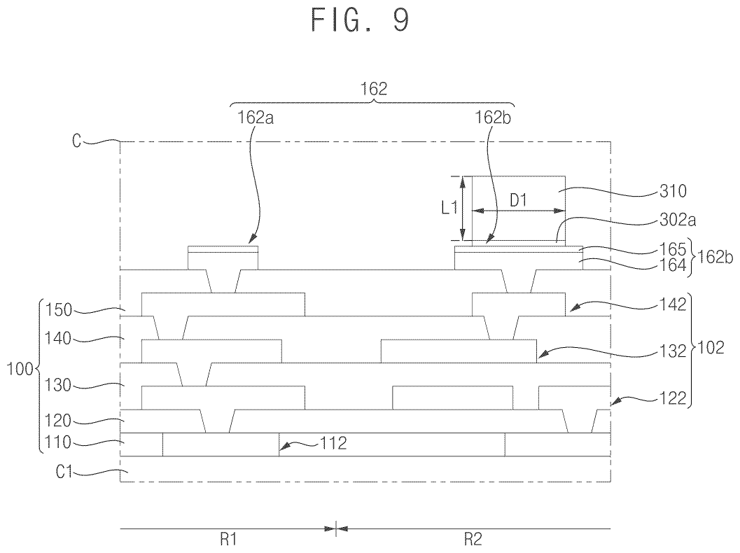

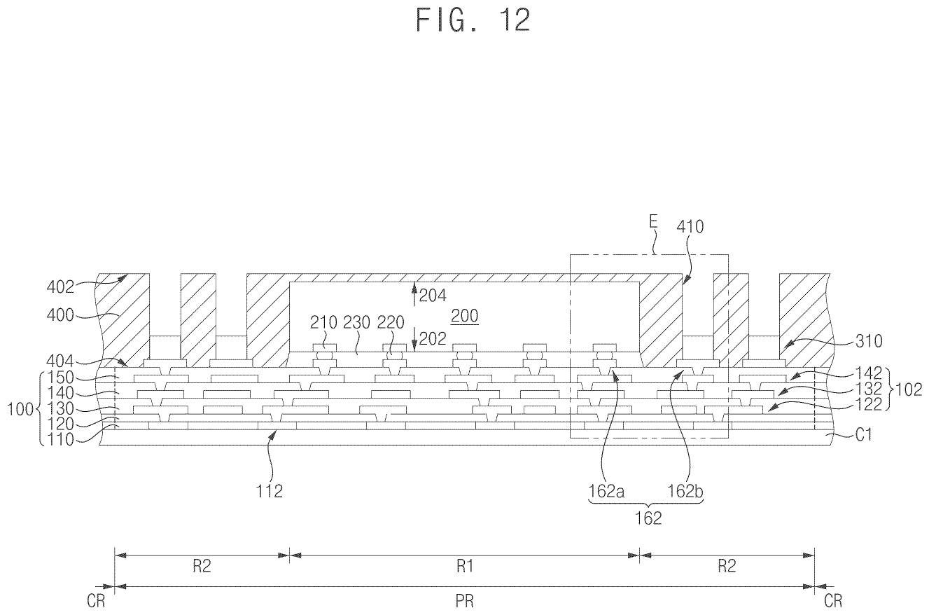

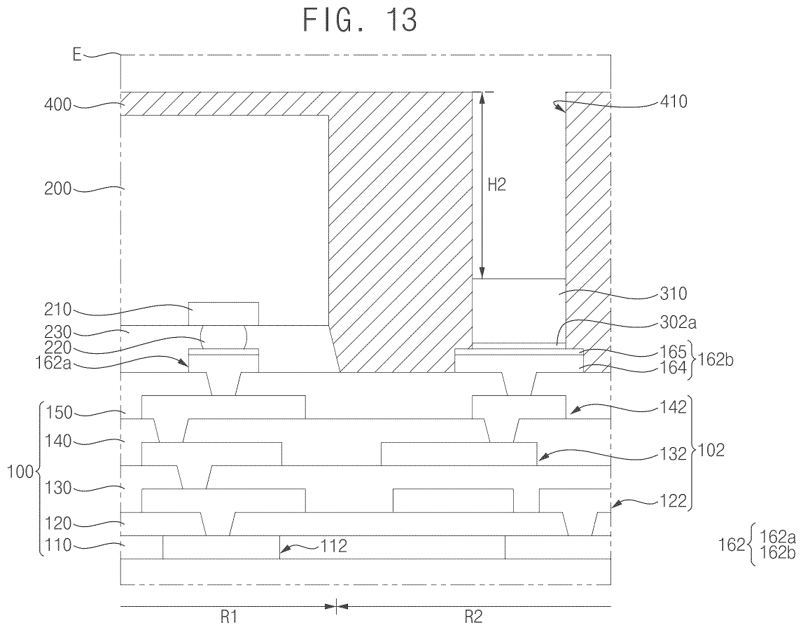

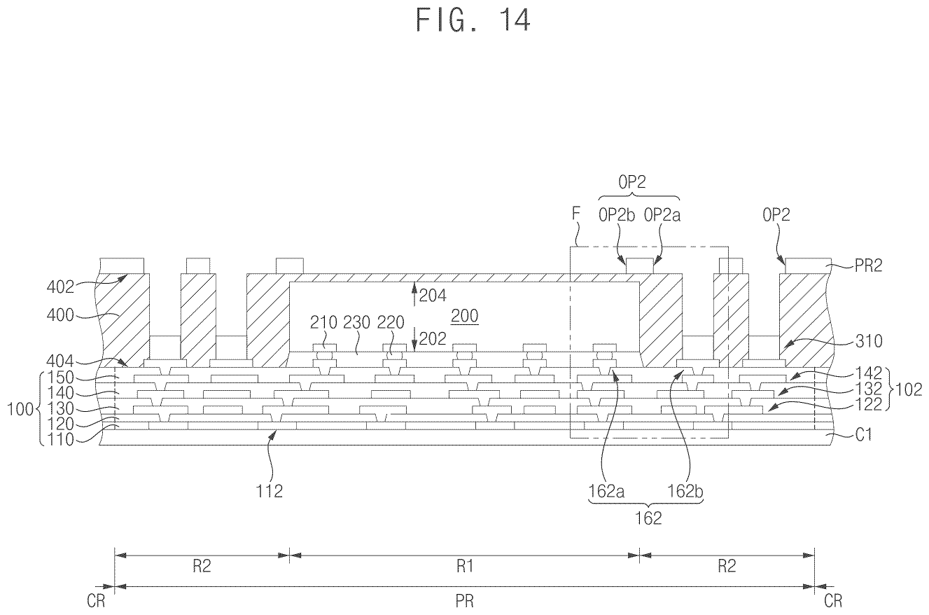

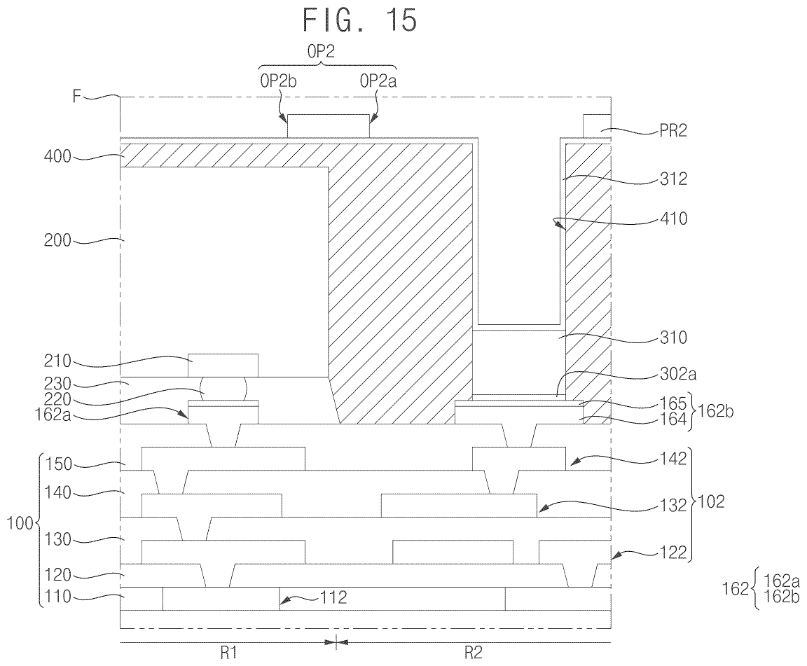

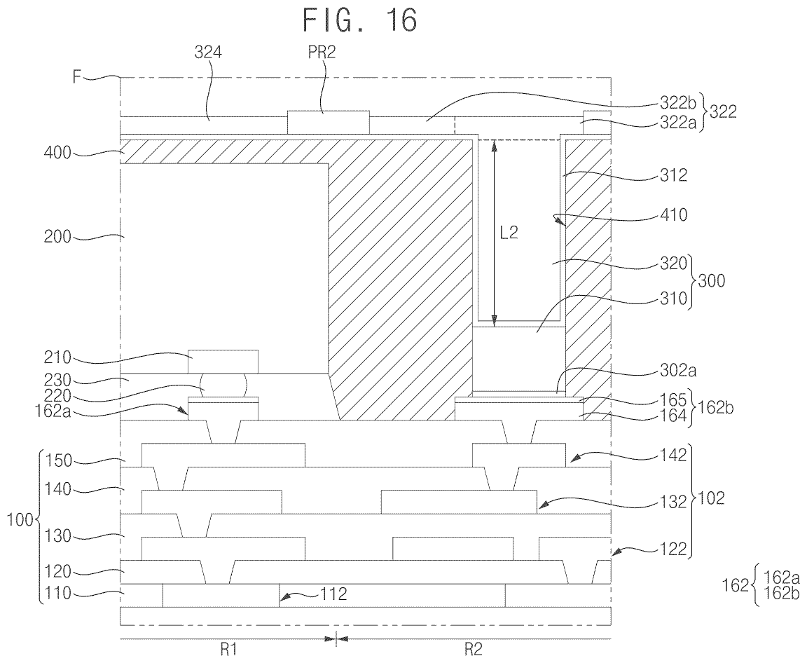

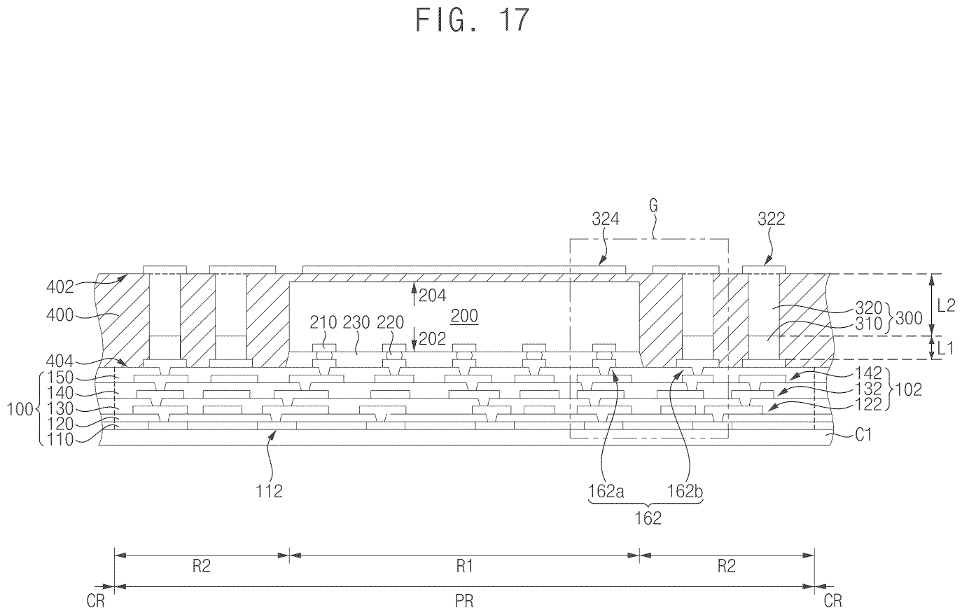

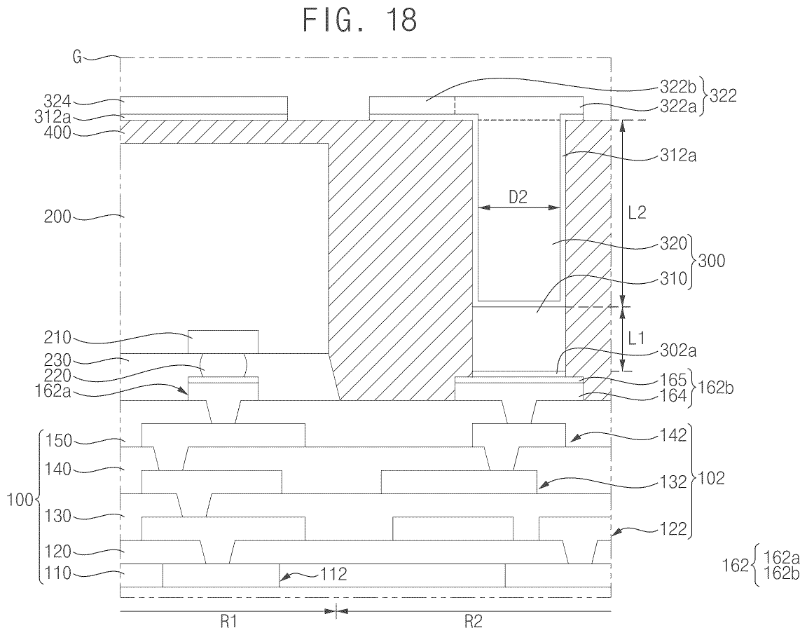

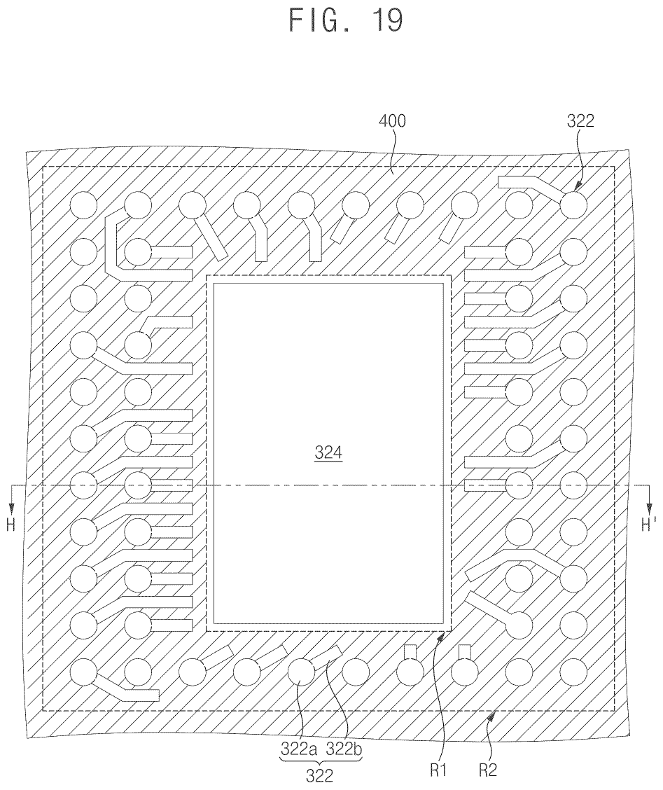

FIGS. 4 to 21 are views illustrating a method of manufacturing a semiconductor package in accordance with example embodiments. FIGS. 4, 8, 10, 11, 12, 14, 17, 20 and 21 are cross-sectional views illustrating a method of manufacturing a semiconductor package in accordance with example embodiments. FIGS. 5 to 7 are enlarged cross-sectional views illustrating portion ‘C’ in FIG. 4. FIG. 9 is an enlarged cross-sectional view illustrating portion ‘D’ in FIG. 8. FIG. 13 is an enlarged cross-sectional view illustrating portion ‘E’ in FIG. 12. FIGS. 15 and 16 are enlarged cross-sectional views illustrating portion ‘F’ in FIG. 14. FIG. 18 is an enlarged cross-sectional view illustrating portion ‘G’ in FIG. 17. FIG. 19 is a plan view of FIG. 17. FIG. 17 is a cross-sectional view taken along the line H-H′ in FIG. 19.

Referring to FIGS. 4 and 5, a lower redistribution wiring layer 100 having first redistribution wirings 102 may be formed on a carrier substrate C1.

In some example embodiments, the carrier substrate C1 may include a wafer substrate as a base substrate for disposing a plurality of semiconductor chips on the lower redistribution wiring layer and forming a molding member covering them. The carrier substrate C1 may have a shape corresponding to a wafer on which a semiconductor process is performed. For example, the carrier substrate C1 may include a silicon substrate, a glass substrate, a non-metal or metal plate, etc.

The carrier substrate C1 may include a package region PR on which the semiconductor chip is mounted and a cutting region CR surrounding the package region PR. As will be described later, the lower redistribution wiring layer 100 and the molding member formed on the carrier substrate C1 may be cut along the cutting region CR that divides the plurality of package regions MR to be individualized.

In some example embodiments, a first lower insulating layer 110 having lower bonding pads 112 formed therein may be formed on the carrier substrate C1. Although it is not illustrated in the figures, after a release film, a barrier metal layer, a seed layer and the first lower insulating layer are sequentially formed on the carrier substrate C1, the first lower insulating layer may be patterned to form openings that exposes first bonding pad regions. Then, a plating process may be performed on the seed layer to form the lower boding pads 112.

For example, the first lower insulating layer 110 may include a polymer or a dielectric layer. The first lower insulating layer 110 may include a photosensitive insulating material such as PID or an insulating film such as ABF. The first lower insulating layer may be formed by a spin coating process, a vapor deposition process, etc.

The lower bonding pad 112 may be a bump pad. The bump pad may include a solder pad or pillar pad. For example, the lower bonding pad may include copper (Cu), aluminum (Al), tin (Sn), nickel (Ni), gold (Au), platinum (Pt), or an alloy thereof.

Then, after a second lower insulating layer 120 is formed on the carrier substrate C1 to cover the lower bonding pads 112, the second lower insulating layer 120 may be patterned to form first openings that expose the lower bonding pads 112.

For example, the second lower insulating layer 120 may include a polymer or a dielectric layer. The second lower insulating layer 120 may include a photosensitive insulating material such as PID or an insulating film such as ABF. The second lower insulating layer may be formed by a spin coating process, a vapor deposition process, etc.

Then, first lower redistribution wirings 122 may be formed on the second lower insulating layer 120 to be electrically connected to the lower bonding pads 112 through the first openings, respectively.

For example, after a seed layer is formed on portions of the second lower insulating layer 120 and in the first opening, the seed layer may be patterned and an electroplating process may be performed to form the first lower redistribution wirings 122. Accordingly, at least portions of the first lower redistribution wirings 122 may directly contact the lower bonding pads 112 through the first openings of the second lower insulating layer 120. For example, the first lower redistribution wiring may include copper (Cu), aluminum (Al), tin (Sn), nickel (Ni), gold (Au), platinum (Pt), or an alloy thereof.

Similarly, after a third lower insulating layer 130 is formed on the second lower insulating layer 120 to cover the first lower redistribution wirings 122, the third lower insulating layer 130 may be patterned to form second openings that expose at least portions of the first lower redistribution wirings 122. Then, second lower redistribution wirings 132 may be formed on the third lower insulating layer 130 to directly contact the first lower redistribution wirings 122 through the second openings of the third lower insulating layer 130.

Then, after a fourth lower insulating layer 140 is formed on the third lower insulating layer 130 to cover the second lower redistribution wirings 132, the fourth lower insulating layer 140 may be patterned to form third openings that expose at least portions of the second lower redistribution wirings 132. Then, third lower redistribution wirings 142 may be formed on the fourth lower insulating layer 140 to directly contact the second lower redistribution wirings 132 through the third openings of the fourth lower insulating layer 140.

Then, a fifth lower insulating layer 150 may be formed on the fourth lower insulating layer 140 to cover the third lower redistribution wirings 142.

Thus, the lower redistribution wiring layer 100 having the first, second, third, fourth and fifth lower insulating layers 110, 120, 130, 140 and 150 may be formed. The lower redistribution wiring layer 100 may be a front redistribution wiring layer (FRDL) of a fan out package. The lower redistribution wiring layer 100 may include the first redistribution wirings 122, 132 and 142 stacked in at least two layers. The lower bonding pads 112 may be exposed from a lower surface of the lower redistribution wiring layer 100. The first redistribution wirings 102 may include the first to third lower redistribution wirings 122, 132 and 142 that are vertically stacked. For example, a thickness of the first redistribution wiring layer 100 may be within a range of 5 μm to 50 μm.

When viewed in plan view, the lower redistribution wiring layer 100 may include the first region R1 as a chip mounting region overlapping with a semiconductor chip to be mounted on the lower redistribution wiring layer 100 as will be described later, and the second region R2 as a connector region surrounding the first region R1 and. The second region R2 may be a fan-out region outside the region where the semiconductor chip is disposed.

Then, upper bonding pads 162 may be formed on the uppermost first redistribution wirings 142 on an upper surface of the lower redistribution wiring layer 100.

For example, the fifth lower insulating layer 150 may be patterned to form openings that expose the third lower redistribution wirings 142 respectively. The third lower redistribution wirings 142 exposed by the openings may be the uppermost redistribution wirings. A portion of the uppermost redistribution wiring may include a redistribution pad portion.

Then, a seed layer may be formed on the fifth lower insulating layer 150, and a photoresist pattern having openings that expose upper bonding pad regions may be formed on the seed layer. The openings may include first openings that expose first bonding pad regions in the first region R1 and second openings that expose second bonding pad regions in the second region R2.

The upper bonding pads 162 may be formed in the openings of the photoresist pattern by a plating process. The upper bonding pads may include a metal material. The upper bonding pads may include the same material as the third lower redistribution wiring 142. The upper bonding pads may include copper (Cu). The upper bonding pads 162 may include a plurality of first bonding pads 162a formed in the first openings and a plurality of second bonding pads 162b formed in the second openings. A diameter of the second bonding pad 162b may be greater than a diameter of the first bonding pad 162a. After removing the photoresist pattern, portions of the seed layer exposed by the upper bonding pads may be removed.

Thus, the upper bonding pads 162 may be formed on the uppermost first redistribution wirings 142 located in the first region R1 and the second region R2 of the lower redistribution wiring layer 100. The upper bonding pads 162 may be exposed from the upper surface of the lower redistribution wiring layer 100. The upper bonding pads 162 may include the first bonding pads 162a as chip connection bonding pads formed on the uppermost first redistribution wirings 142 located in the first region R1, and the second bonding pads 162b as conductive structure connection bonding pads formed on the uppermost first redistribution wirings 142 located within the second region R2.

For example, the upper bonding pads 162 may have a multilayer structure. The upper bonding pad 162 may include a bonding pad pattern 164 and a plating pad pattern 165 formed on the bonding pad pattern 164. The bonding pad pattern 164 may include copper (Cu), and the plating pad pattern 165 may include nickel (Ni), gold (Au), or titanium (Ti).

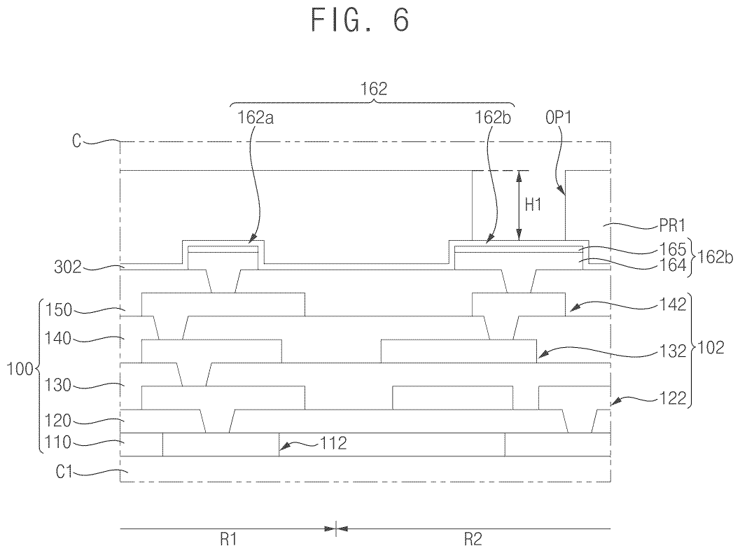

Referring to FIGS. 6 to 9, a plurality of first conductive pillars 310 may be formed on the plurality of second bonding pads 162b located in the fan-out region R2, respectively.

As illustrated in FIG. 6, a seed layer 302 may be formed on the upper surface of the lower redistribution wiring layer 100 to cover the second bonding pads 162b, and a first photoresist pattern PR1 having first openings OP1 that expose first conductive pillar regions may be formed on the seed layer 302. The first openings OP1 may expose at least portions of the plurality of second bonding pads 162b in the second region R2. The first openings OP1 may have a depth H1 within a range of 50 μm to 100 μm from the upper surface of the first photoresist pattern PR1.

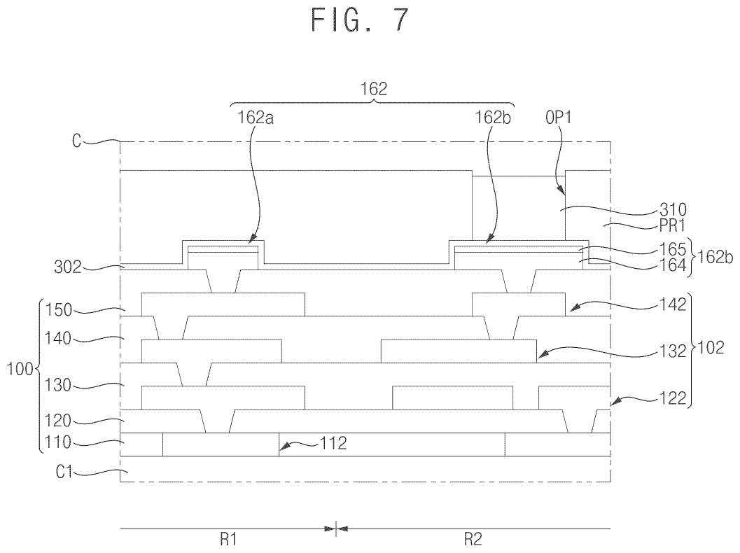

As illustrated in FIG. 7, an electrolytic plating process may be performed on the seed layer 302 to fill the first openings OP1 of the first photoresist pattern PR1 with a conductive material to form the first conductive pillars 310. For example, the first conductive pillar 310 may include copper (Cu). A lower portion of the first conductive pillar 310 may be bonded to the plating pad pattern 165 of the second bonding pad 162b.

As illustrated in FIGS. 8 and 9, the first photoresist pattern PR1 may be removed by a strip process. Accordingly, in some example embodiments, the first conductive pillars 310 may extend upward from the second bonding pads 162b on the first redistribution wirings 102 of the first redistribution wiring layer 100, for example, the third uppermost redistribution wirings 142 respectively. For example, a first diameter D1 of the first conductive pillar 310 may be in a range of 50 μm to 200 μm, and a first length L1 of the first conductive pillar 310 may be in a range of 50 μm to 100 μm.

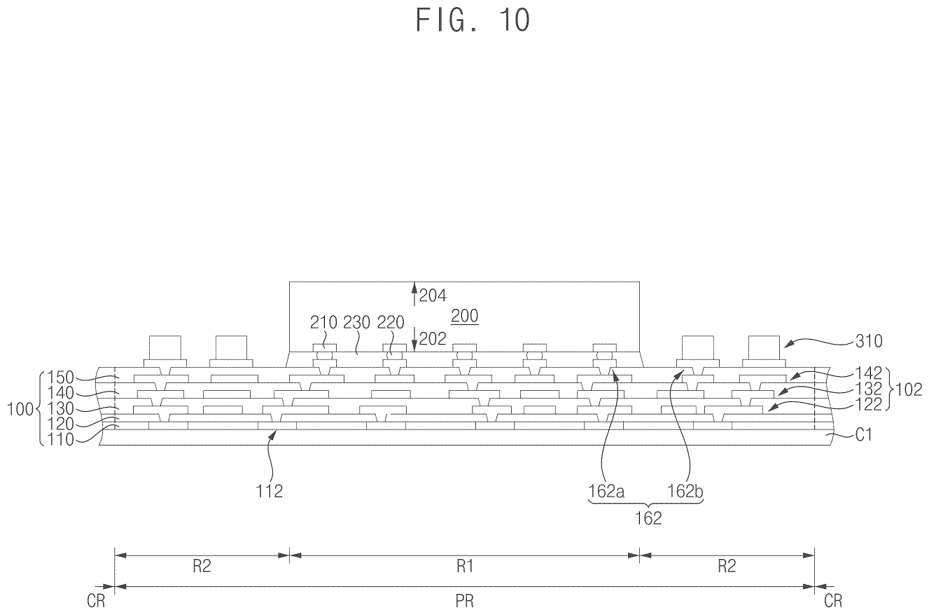

Referring to FIG. 10, at least one semiconductor chip 200 may be mounted on the upper surface of the lower redistribution wiring layer 100.

In some example embodiments, the semiconductor chip 200 may be disposed in the first region R1 as a fan-in region of the lower redistribution wiring layer 100. The semiconductor chip 200 may be mounted on the upper surface of the lower redistribution wiring layer 100 by a flip chip bonding method. The semiconductor chip 200 may be disposed such that a front surface 202 on which chip pads 210 are formed, for example, an active surface, faces the lower redistribution wiring layer 100. The chip pads 210 of the semiconductor chip 200 may be electrically connected to the first redistribution wirings 102 of the lower redistribution wiring layer 100 by conductive bumps 220. The conductive bumps 220 may be bonded to the first bonding pads 162a on the uppermost first redistribution wirings 142, respectively. For example, the conductive bumps 220 may include micro bumps (uBumps).

An underfill member 230 may be underfilled between the semiconductor chip 200 and the lower redistribution wiring layer 100. The underfill member may include a material having relatively high fluidity to effectively fill a small space between the semiconductor chip and the lower redistribution wiring layer. For example, the underfill member may include an adhesive containing an epoxy material.

The semiconductor chip may be a logic chip including a logic circuit. The logic chip may be a controller that controls memory chips. The semiconductor chip may be a processor chip such as an ASIC or an application processor (AP) serving as a host such as a CPU, GPU, or SOC.

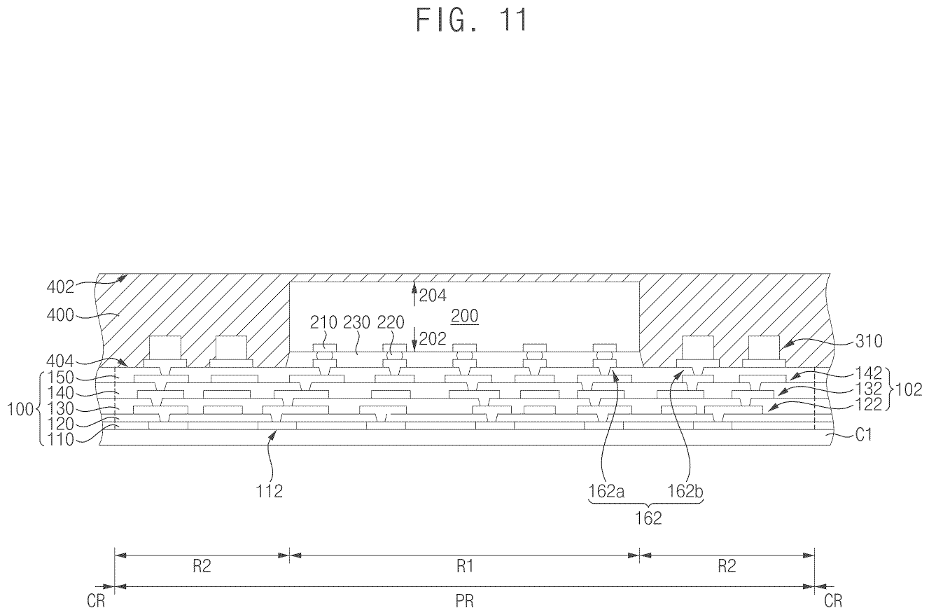

Referring to FIG. 11, a molding member 400 may be formed on the upper surface of the lower redistribution wiring layer 100 to cover the semiconductor chip 200 and the plurality of the first conductive pillars 310.

For example, the molding member 400 may include an epoxy molding compound (EMC). The molding member 400 may include UV resin, polyurethane resin, silicone resin, silica filler, etc.

The molding member 400 may include a first molding portion that covers a backside surface 204 of the semiconductor chip 200, for example, an upper surface and a second molding portion that covers the upper surface of the lower redistribution wiring layer 100 around the semiconductor chip 200.

Referring to FIGS. 12 to 19, second conductive pillars 320 may be formed to penetrate the molding member 400 and may be stacked on the first conductive pillars 310 respectively.

As illustrated in FIGS. 12 and 13, a laser processing may be performed on an upper surface 402 of the molding member 400 to form recesses 410 that expose upper surfaces of the first conductive pillars 310, respectively. For example, the recesses 410 may be formed by a laser drilling process. Lasers in the laser drilling process may include CO₂ laser, YAG laser, excimer laser, UV laser, etc.

The recesses 410 may have a predetermined depth H2 from the upper surface 402 of the molding member 400 and may expose at least portions of the plurality of first conductive pillars 310 in the second region R2. The depth H2 of the recess 410 may be within a range of 200 μm to 300 μm from the upper surface 402 of the molding member 400.

As illustrated in FIGS. 14 and 15, a seed layer 312 may be formed on the upper surface 402 of the molding member 400 to cover inner surfaces of the recesses 410, and a second photoresist pattern PR2 having second openings OP2 that expose second conductive pillar regions may be formed on the seed layer 312. The second openings OP2 may include a third opening OP2a for forming a first upper redistribution wiring and a fourth opening OP2b for forming a heat dissipation pattern. The third opening OP2a for forming the first upper redistribution wiring may expose the recess 410 and a portion of the upper surface 402 of the molding member 400 around the recess 410. The fourth opening OP2b for forming the heat dissipation pattern may expose at least a portion of the upper surface of the first molding portion of the molding member 400 that covers the backside surface 204 of the semiconductor chip 200.

As illustrated in FIG. 16, an electrolytic plating process may be performed on the seed layer 312 to fill the recess 410 of the molding member 400 with a conductive material to form the second conductive pillar 320. Additionally, the electrolytic plating process may be performed on the seed layer 312 to fill the third opening OP2a for forming the first upper redistribution wiring of the second photoresist pattern PR2 with the conductive material to form a first upper redistribution wiring 322 and to fill the fourth opening OP2b for forming the heat dissipation pattern with the conductive material to form a heat dissipation pattern 324.

As illustrated in FIGS. 17 to 19, the second photoresist pattern PR2 may be removed by a strip process. Accordingly, in some example embodiments, vertical conductive structures 300 including the first conductive pillars 310 that extends upward the second bonding pads 162b on the first redistribution wirings 102 of the first redistribution wiring layer 100, for example, the third uppermost redistribution wirings 142, and the second conductive pillars 320 that are stacked on the first conductive pillars 310 respectively may be formed.

For example, the second conductive pillar 320 may include copper (Cu). A second diameter D2 of the second conductive pillar 320 may be within a range of 30 μm to 180 μm, and a second length L2 of the second conductive pillar 320 may be within a range of 200 μm to 300 μm. The length L2 of the second conductive pillar 320 may be at least twice the length L1 of the first conductive pillar 310.

The first upper redistribution wiring 322 may be formed on an upper end portion of the second conductive pillar 320. The first upper redistribution wiring 322 may include a redistribution pad 322a that is provided on the upper end portion of the second conductive pillar 320 and a redistribution line 322b that extends from the redistribution pad 322a on the upper surface 402 of the molding member 400. The heat dissipation pattern 324 may extend to cover at least a portion of the backside surface 204 of the semiconductor chip 200. An upper surface of the first upper redistribution wiring 322 may be located on the same plane as an upper surface of the heat dissipation pattern 324. The first upper redistribution wiring 322 and the heat dissipation pattern 324 may include the same metal material, for example, copper (Cu).

Accordingly, in some example embodiments, the plurality of vertical conductive structures 300 may extend to penetrate the molding member 400 on the upper surface of the fan-out region R2 of the lower redistribution wiring layer 100. The vertical conductive structure 300 may function as a through mold via (TMV) formed through the second molding portion of the molding member 400.

Since the vertical conductive structure 300 includes the first conductive pillar 310 formed by a first plating process and the second conductive pillar 320 formed within the recess 410 of the molding member 400 by a second plating process after the first plating process, the length of the vertical conductive structure 300 may be increased. Thus, the semiconductor chip 200 having a relatively greater thickness may be applied to thereby improve heat dissipation characteristics of the semiconductor chip 200.

Additionally, since the first upper redistribution wiring 322 and the heat dissipation pattern 324 are simultaneously formed when forming the second conductive pillar 320, process steps may be reduced and heat dissipation performance of the semiconductor package may be improved.

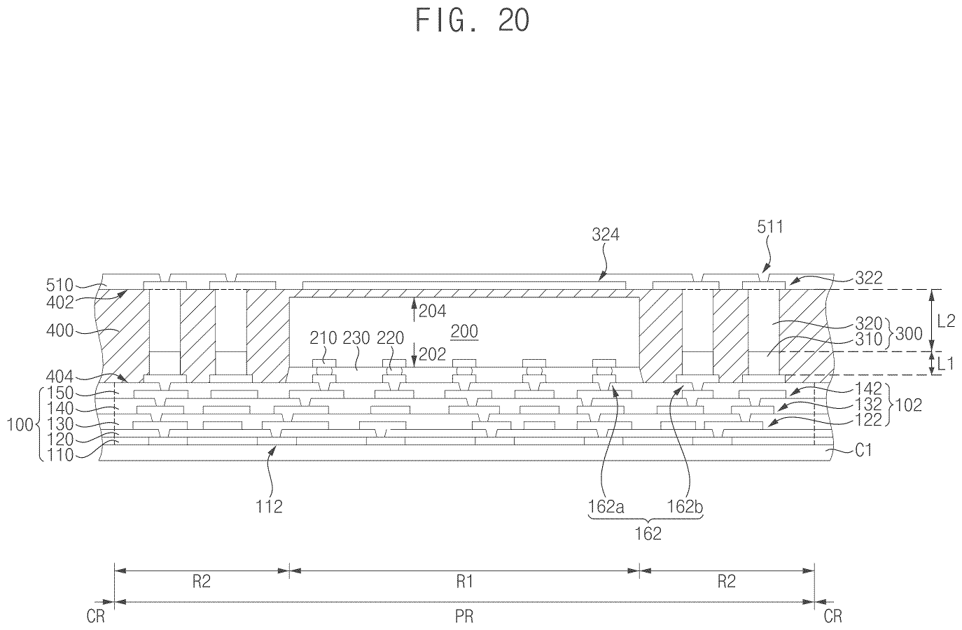

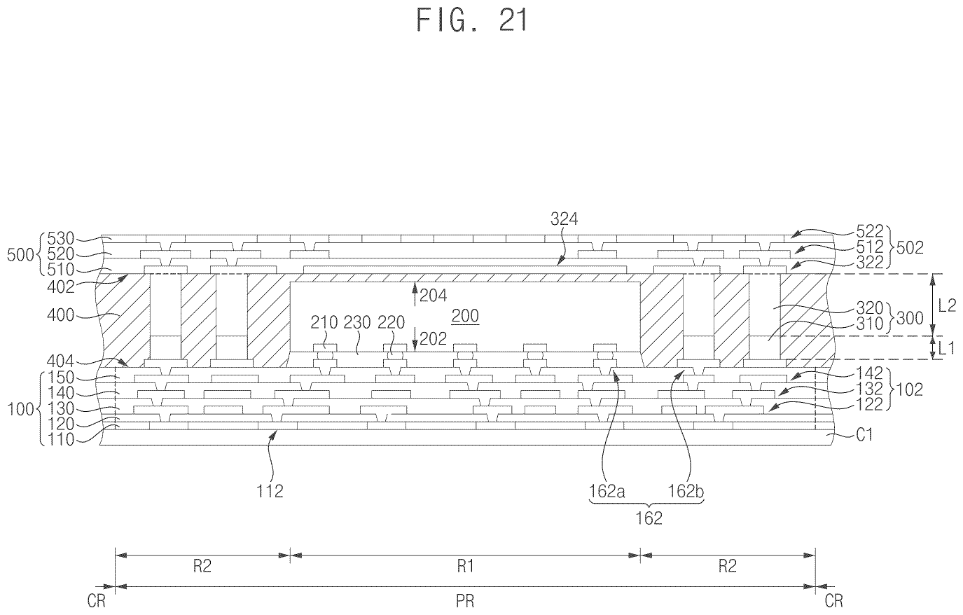

Referring to FIGS. 20 and 21, an upper redistribution wiring layer 500 having second redistribution wirings 502 electrically connected to the vertical conductive structures 300 may be formed on the upper surface 402 of the molding member 400.

As illustrated in FIG. 20, after a first upper insulating layer 510 is formed on the upper surface 402 of the molding member 400, the first upper insulating layer 510 may be patterned to form openings 511 that expose upper end portions of the vertical conductive structures 300, for example, the first upper redistribution wirings 322 respectively. The first upper insulating layer 510 may include a polymer, a dielectric layer, etc. The first upper insulating layer 510 may be formed by a vapor deposition process, spin coating process, etc.

As illustrated in FIG. 21, after a seed layer is formed on portions of the exposed first upper redistribution wirings 322 and in the openings 511, the seed layer may be patterned and an electro plating process may be performed to form the second upper redistribution wirings 512 may be formed. Accordingly, in some example embodiments, at least portions of the second upper redistribution wirings 512 may be electrically connected the upper end portions of the vertical conductive structures 300, for example, the first upper redistribution wirings 322 through the openings 511. The second upper redistribution may include aluminum (Al), copper (Cu), tin (Sn), nickel (Ni), gold (Au), platinum (Pt), or an alloy thereof.

Then, after a second upper insulating layer 520 is formed on the first upper insulating layer 510, the second upper insulating layer 520 may be patterned to form openings that expose the second upper redistribution wirings 5122. Then, third upper redistribution wirings 522 may be formed on the second upper insulating layer 520 to directly contact the second upper redistribution wirings 512 through the openings of the second upper insulating layer 520.

Accordingly, in some example embodiments, the second redistribution wirings 502 may include the first upper redistribution wirings 322, the second upper redistribution wiring 512 and the third upper redistribution wiring 522 stacked at least two layers. For example, the first upper redistribution wiring 322 may correspond to a lowermost redistribution wiring among the second redistribution wirings, and the third upper redistribution wiring 522 may correspond to an uppermost redistribution wiring among the second redistribution wirings.

Then, upper bonding pads (not illustrated) may be formed on the third upper redistribution wirings 522 as the uppermost redistribution wirings respectively, and a third upper insulating layer 530 may be formed on the second upper insulating layer 520 and may expose at least a portion of the second bonding pad on the third upper redistribution wiring 522. The third upper insulating layer 530 may serve as a passivation layer.

Thus, the second redistribution wiring layer 500 as a backside redistribution wiring layer (BRDL) having the second redistribution wirings 502 may be formed on the molding member 400. The second redistribution wiring layer 500 may include the first to third upper insulating layer 510, 520 and 530 sequentially stacked and the second redistribution wirings 502 within the stacked first to third upper insulating layers 510, 520 and 530. The second redistribution wirings 502 may include the first, second and third upper redistribution wirings 322, 512 and 522.

It will be understood that the number, size, and arrangement of the upper insulating layers and the upper redistribution wirings of the second redistribution wiring layer are provided as examples, and the present inventive concepts are not limited thereto.

Then, the carrier substrate C1 may be removed, and external connection members 600 (see FIG. 1) may be formed on the lower bonding pads 112 on a lower surface of the lower redistribution wiring layer 100.

Then, a sawing process may be performed to individualize the lower redistribution wiring layers 100 to complete the fan out wafer level package 10 of FIG. 1 including the molding member 400, the lower redistribution wiring layer 100 formed on a lower surface 404 of the molding member 400 and the upper redistribution wiring layer 500 formed on the upper surface 402 of the molding member 400.

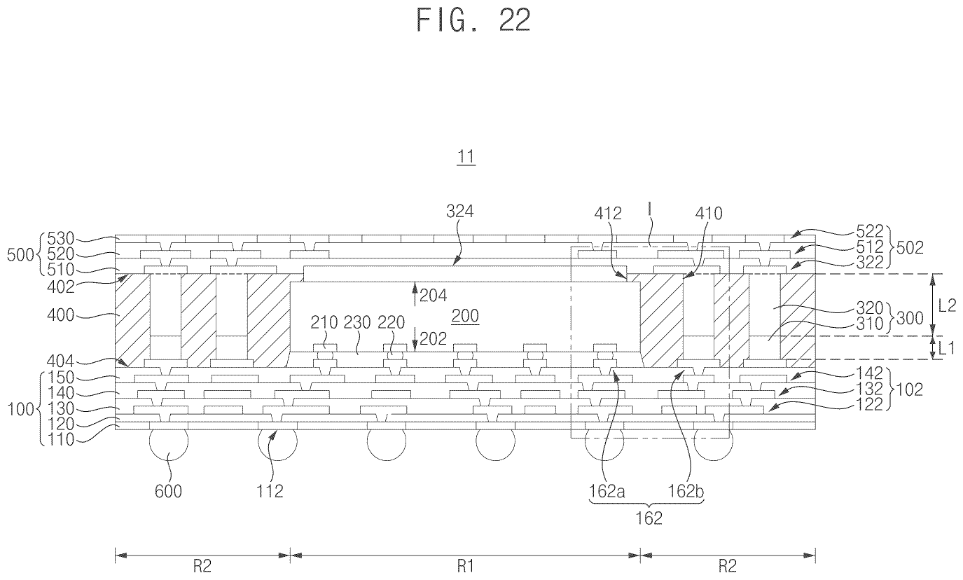

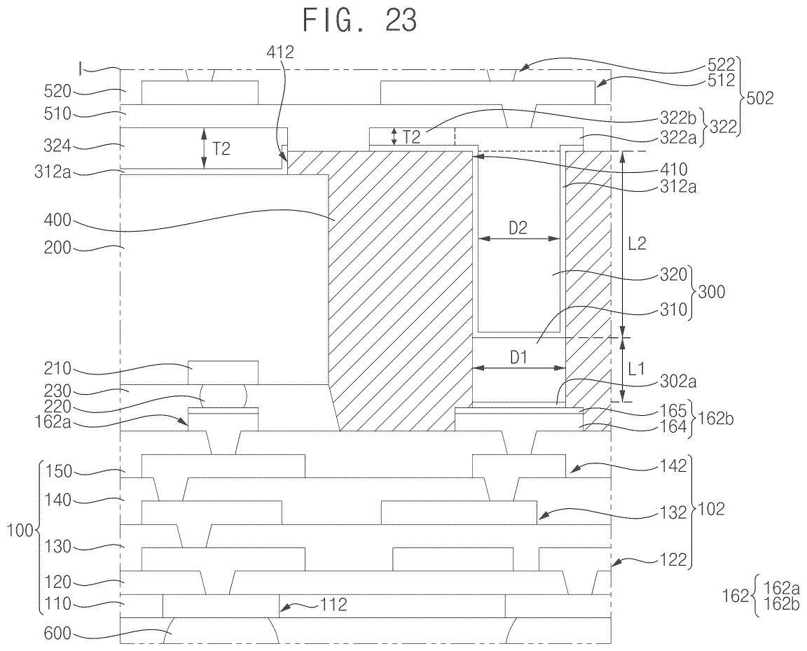

FIG. 22 is a cross-sectional view illustrating a semiconductor package in accordance with example embodiments. FIG. 23 is an enlarged cross-sectional views illustrating portion ‘I’ in FIG. 22. The semiconductor package may be substantially the same as the semiconductor package described with reference to FIGS. 1 to 3 except for a molding member and a heat dissipation pattern. Thus, same reference numerals may be used to refer to the same or like elements and any further repetitive explanation concerning the above elements will be omitted.

Referring to FIGS. 22 and 23, a semiconductor package 11 may include a lower redistribution wiring layer 100, a semiconductor chip 200, a molding member 400, vertical conductive structures 300, and an upper redistribution wiring layer 500.

In some example embodiments, the molding member 400 may expose at least a portion of a backside surface 204 of the semiconductor chip 200. A second recess 412 may be formed in an upper surface 402 of the molding member 400 to expose the at least a portion of the backside surface 204 of the semiconductor chip 200. A heat dissipation pattern 324 may be provided to fill the second recess 312. The heat dissipation pattern 324 may directly contact the backside surface 204 of the semiconductor chip 200 exposed by the second recess 412. The heat dissipation pattern 324 may protrude from the upper surface 402 of the molding member 400. A thickness T2 of the heat dissipation pattern 324 may be greater than a thickness T1 of a first upper redistribution wiring 322. An upper surface of the heat dissipation pattern 324 may be located on the same plane as an upper surface of the first upper redistribution wiring 322.

Hereinafter, a method of manufacturing the semiconductor package of FIG. 22 will be described.

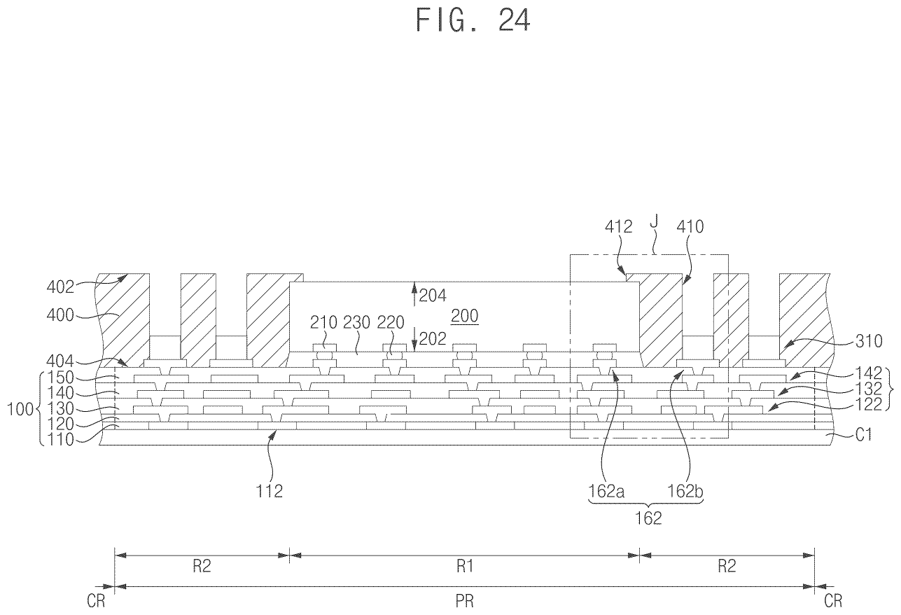

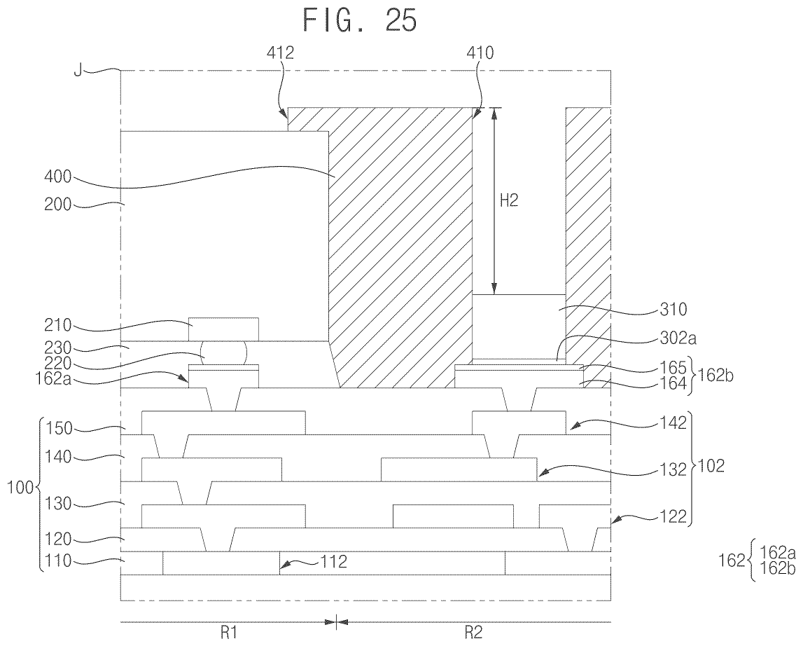

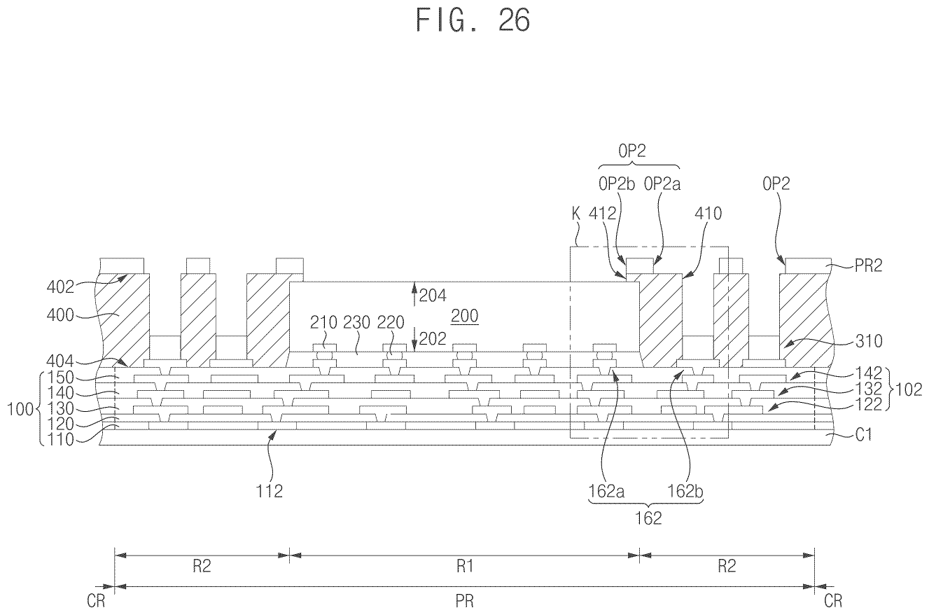

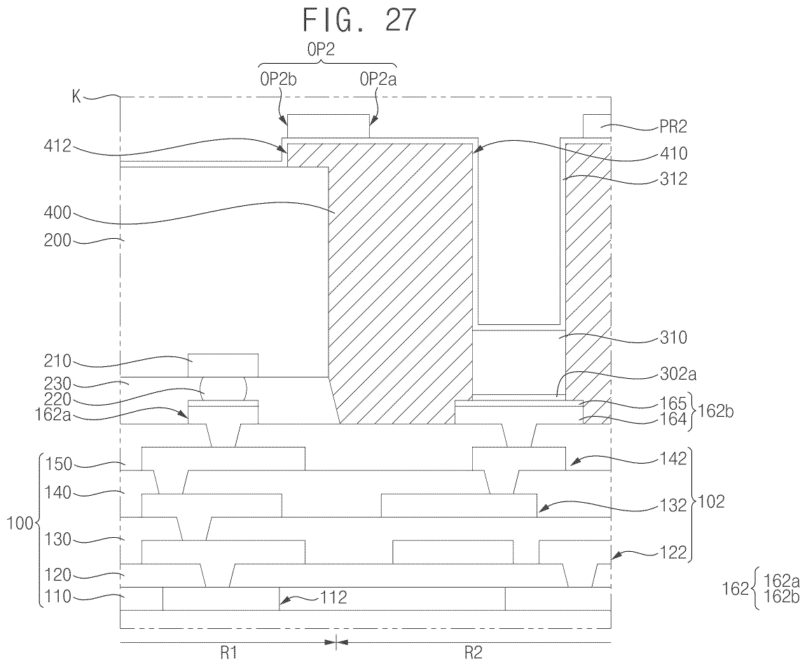

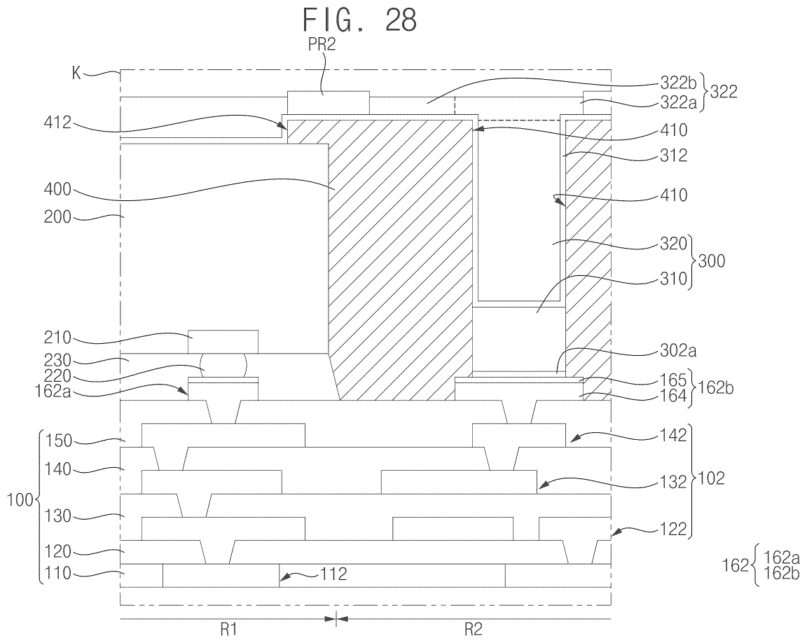

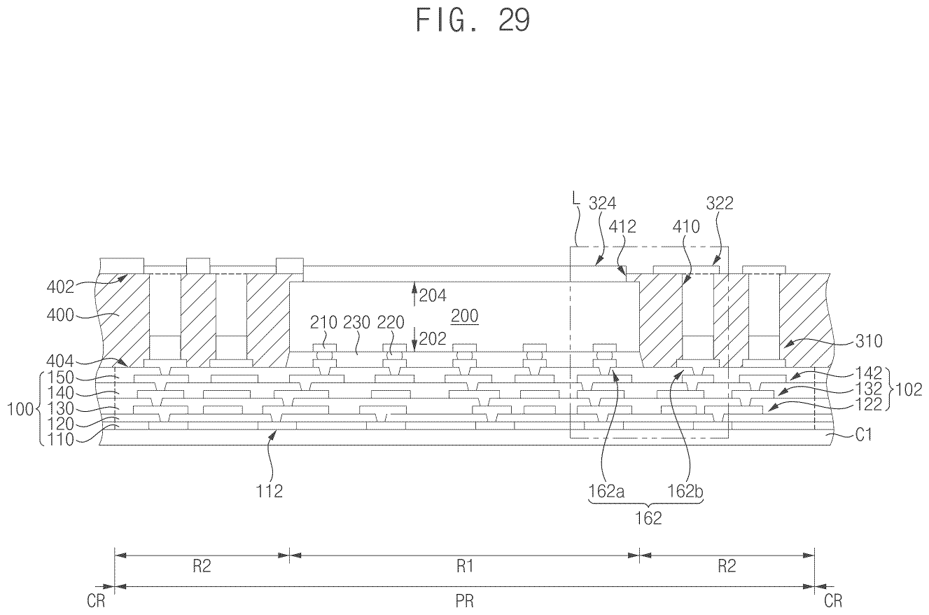

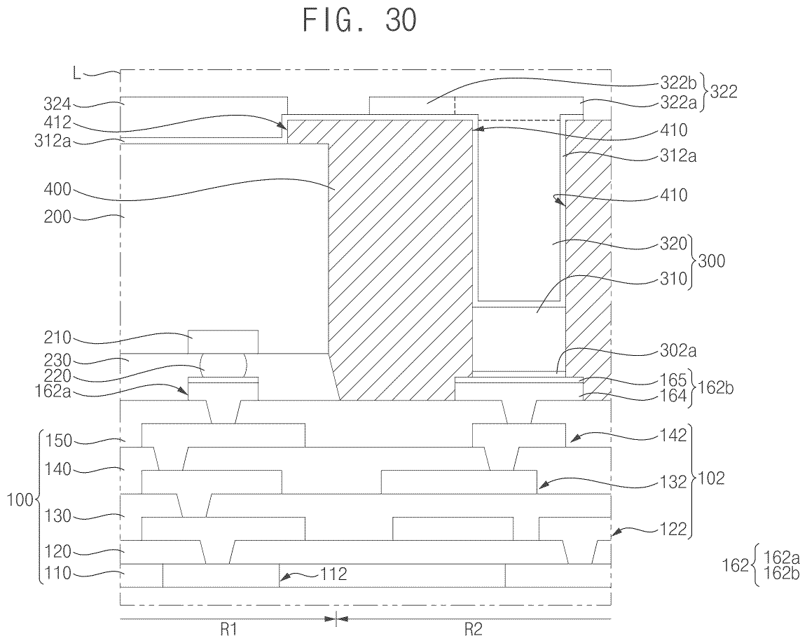

FIGS. 24 to 30 are cross-sectional views illustrating a method of manufacturing a semiconductor package in accordance with example embodiments. FIGS. 24, 26 and 29 are cross-sectional views illustrating a method of manufacturing a semiconductor package in accordance with example embodiments. FIG. 25 is an enlarged cross-sectional view illustrating portion ‘J’ in FIG. 24. FIGS. 27 and 28 are enlarged cross-sectional views illustrating portion ‘K’ in FIG. 26. FIG. 30 is an enlarged cross-sectional view illustrating portion ‘L’ in FIG. 29.

Referring to FIGS. 24 and 25, processes the same as or similar to the processes described with reference to FIGS. 4 to 13 may be performed to form a molding member 400 on an upper surface of a lower redistribution wiring layer 100 to cover a semiconductor chip 200 and a plurality of first conductive pillars 310, and laser processing may be performed on an upper surface 402 of the molding member 400 to form first recesses 410 that expose the upper surfaces of the first conductive pillars 310 respectively and a second recess 412 that exposes at least a portion of a backside surface 204 of the semiconductor chip 200.

The recess 410 and the second recess 420 may be formed by a laser milling process. The recess 410 may be formed by performing the laser milling process on a second molding portion of the molding member 400 that covers the first conductive pillar 310 in a second region R2. The recess 410 may extend in a thickness direction from the upper surface 402 of the molding member 400 to expose at least a portion of the first conductive pillar 310 in the second region R2. The second recess 412 may be formed by performing the laser milling process on a first molding portion of the molding member 400 that covers the backside surface 204 of the semiconductor chip 200 in a first region R1. The second recess 412 may extend in a thickness direction from the upper surface of the first molding portion of the molding member 400 to expose at least a portion of the backside surface 204 of the semiconductor chip 200.

Referring to FIGS. 26 and 27, a seed layer 312 may be formed on the upper surface 402 of the molding member 400 to cover inner surfaces of the first recesses 410 and the second recess 412, a second photoresist pattern PR2 having second openings OP2 that expose second conductive pillar regions may be formed on the seed layer 312. The seed layer 312 may be formed on the backside surface 204 of the semiconductor chip 200 exposed by the second recess 412. The second openings OP2 may include a third opening OP2a for forming a first upper redistribution wiring and a fourth opening OP2b for forming a heat dissipation pattern. The third opening OP2a for forming the first upper redistribution wiring may expose the first recess 410 and a portion of the upper surface 402 of the molding member 400 around the recess 410. The fourth opening OP2b for forming the heat dissipation pattern may expose the second recess 412 and at least a portion of the upper surface of the first molding portion of the molding member 400 around the second recess 412.

Referring to FIG. 28, an electrolytic plating process may be performed on the seed layer 312 to fill the first recess 410 of the molding member 400 with a conductive material to form a second conductive pillar 320. Additionally, the electrolytic plating process may be performed on the seed layer 312 to fill the third opening OP2a among the second openings OP2 of the second photoresist pattern PR2 with a conductive material to form a first upper redistribution wiring 322 and to fill the fourth opening OP2b among the second openings OP2 with a conductive material to form the heat dissipation pattern 324.

The heat dissipation pattern 324 may fill the second recess 412 of the molding member 400. The heat dissipation pattern 324 may directly contact the backside surface 204 of the semiconductor chip 200.

Referring to FIGS. 29 and 30, the second photoresist pattern PR2 may be removed by a strip process. Accordingly, in some example embodiments, vertical conductive structures 300 including the first conductive pillars 310 that extends upward from the second bonding pads 162b on the first redistribution wirings 102 of the first redistribution wiring layer 100, for example, the third uppermost redistribution wirings 142 and the second conductive pillars 320 that are stacked on the first conductive pillars 310 respectively may be formed.

The first upper redistribution wiring 322 may be formed on an upper end portion of the second conductive pillar 320. The first upper redistribution wiring 322 may include a redistribution pad 322a provided on the upper end portion of the second conductive pillar 320 and a redistribution line 322b extending from the redistribution pad 322a on the upper surface 402 of the molding member 400.

The heat dissipation pattern 324 may extend to cover at least a portion of the backside surface 204 of the semiconductor chip 200. An upper surface of the first upper redistribution wiring 322 may be located on the same plane as an upper surface of the heat dissipation pattern 324. The first upper redistribution wiring 322 and the heat dissipation pattern 324 may include the same metal material, for example, copper (Cu).

Then, processes the same as or similar to the processes described with reference to FIGS. 20 and 21 may be performed to form second redistribution wirings 502 that are electrically connected to the vertical conductive structures 300 on the upper surface 402 of the molding member 400 and external connection members 600 (see FIG. 22) may be formed on lower bonding pads 112 on a lower surface of the lower redistribution wiring layer 100.

Then, a sawing process may be performed to individualize the lower redistribution wiring layers 100 to complete the fan out wafer level package 11 of FIG. 22 including the molding member 400, the lower redistribution wiring layer 100 formed on a lower surface 404 of the molding member 400 and the upper redistribution wiring layer 500 formed on the upper surface 402 of the molding member 400.

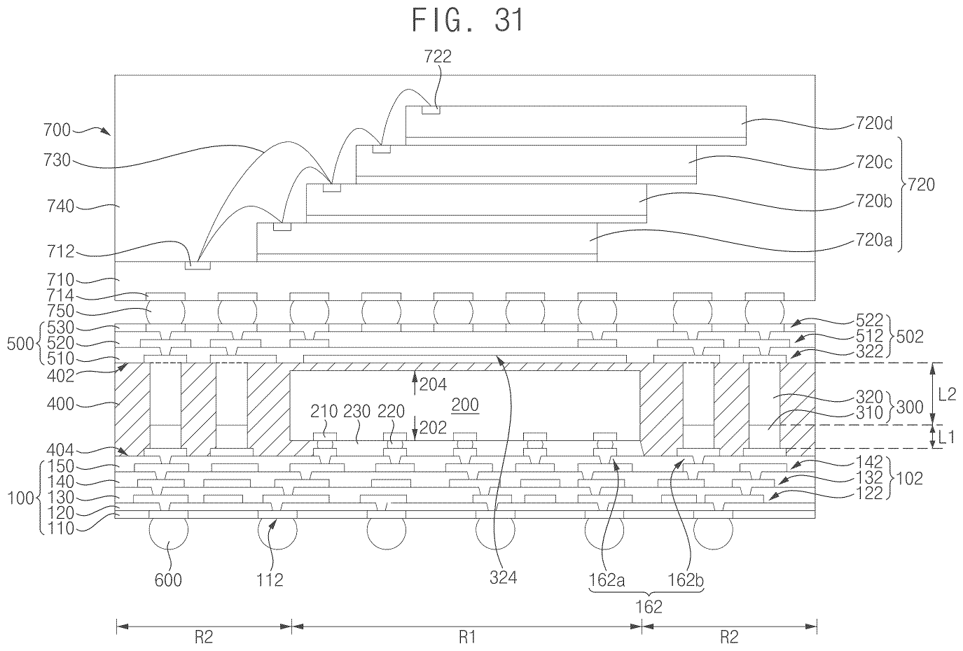

FIG. 31 is a cross-sectional view illustrating a semiconductor package in accordance with example embodiments. The semiconductor package may be substantially the same as the semiconductor package described with reference to FIGS. 1 to 3 except for an additional second package. Thus, same reference numerals may be used to refer to the same or like elements and any further repetitive explanation concerning the above elements will be omitted.

Referring to FIG. 31, a semiconductor package 12 may include a first package and a second package 700 stacked on the first package. The first package may include a lower redistribution wiring layer 100, a semiconductor chip 200, a molding member 400 and an upper redistribution wiring layer 500. The first package may be substantially the same as or similar to the unit package described with reference to FIG. 1.

In some example embodiments, the second package 700 may include a second package substrate 710, a plurality of second semiconductor chips 720 mounted on the second package substrate 710 and a molding member 740 covering the second semiconductor chips 720 on the second package substrate 710.

The second package 700 may be stacked on the first package via conductive connection members 750. For example, the conductive connection members 750 may include solder balls, conductive bumps, etc. The conductive connection member 750 may be disposed between an upper bonding pad on a third upper redistribution wiring 522 of the upper redistribution wiring layer 500 and a second connection pad 714 of the second package substrate 710. Accordingly, in some example embodiments, the first package and the second package 700 may be electrically connected to each other by the conductive connection members 750.

A plurality of second semiconductor chips 720a, 720b, 720c and 720d may be sequentially stacked on the second package substrate 710 by adhesive members. Bonding wires 730 may connect second chip pads 722 of the second semiconductor chips 720 to first connection pads 712 of the second package substrate 710. The second semiconductor chips 720 may be electrically connected to the second package substrate 710 by the bonding wires 730.

Although the second package 700 includes four semiconductor chips mounted by a wire bonding method, it will be understood that the number of the semiconductor chips in the second package and the mounting method are not limited thereto.

In some example embodiments, the semiconductor package 12 may further include a heat sink (not illustrated) stacked on the second package 700. The heat sink 700 may be provided on the second package 700 to dissipate heat from the first and second packages to the outside. The heat sink may be attached on the second package 700 by a thermal interface material (TIM).

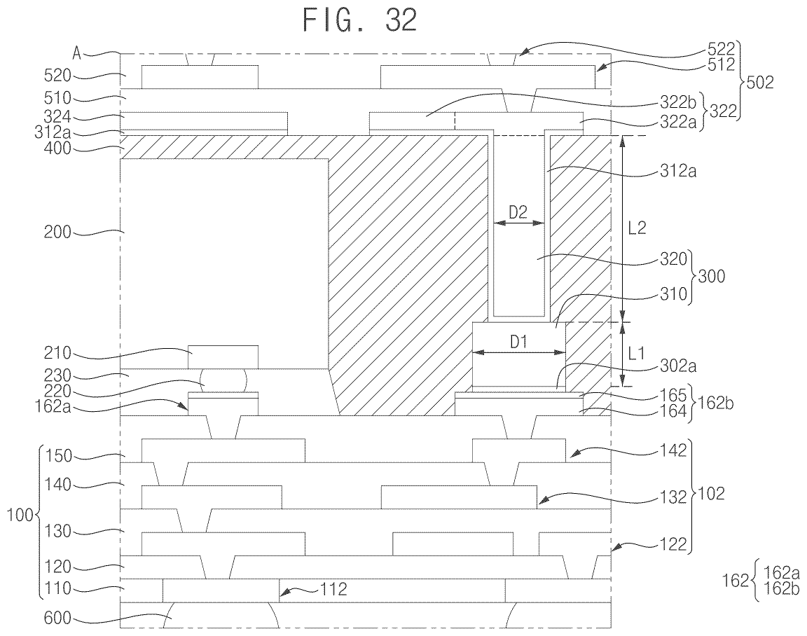

FIG. 32 is a cross-sectional view illustrating a semiconductor package in accordance with some example embodiments. FIG. 32 is an enlarged cross-sectional view illustrating portion ‘A’ in FIG. 1. The semiconductor package may be substantially the same as the semiconductor package described with reference to FIG. 1 except for a vertical conductive structure. Thus, same reference numerals may be used to refer to the same or like elements and any further repetitive explanation concerning the above elements will be omitted.

Referring to FIG. 32, a vertical conductive structure 300 may include a first conductive pillar 310 on a second bonding pad 162b and a second conductive pillar 320 stacked on the first conductive pillar 310.

In some example embodiments, the first conductive pillar 310 may have a first diameter D1, and the second conductive pillar 320 may have a second diameter D2 that is less than the first diameter D1. For example, the first diameter D1 of the first conductive pillar 310 may be in a range of 50 μm to 180 μm, and a second diameter D2 of the second conductive pillar 320 is in a range of 30 μm to 120 μm.

Additionally, a central axis of the first conductive pillar 310 may be arranged to be aligned or offset from a central axis of the second conductive pillar 320.

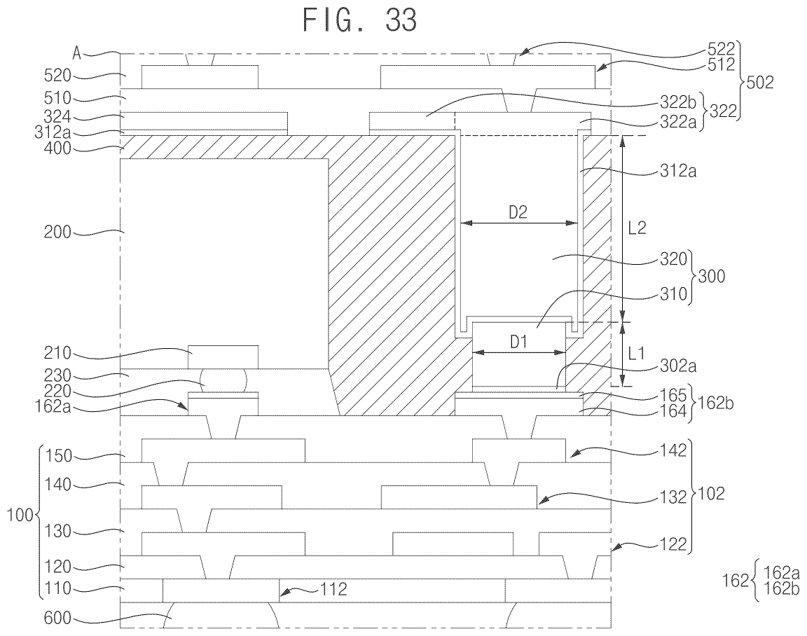

FIG. 33 is a cross-sectional view illustrating a semiconductor package in accordance with example embodiments. FIG. 33 is an enlarged cross-sectional view illustrating portion ‘A’ in FIG. 1. The semiconductor package may be substantially the same as the semiconductor package described with reference to FIG. 1 except for a vertical conductive structure. Thus, same reference numerals may be used to refer to the same or like elements and any further repetitive explanation concerning the above elements will be omitted.

Referring to FIG. 33, a first conductive pillar 310 may have a first diameter D1, and a second conductive pillar 320 may have a second diameter D2 that is greater than the first diameter D1. For example, the first diameter D1 of the first conductive pillar 310 may be in a range of 30 μm to 120 μm, and the second diameter D2 of the second conductive pillar 320 may be in a range of 50 μm to 200 μm.

For example, a lower portion of the second conductive pillar 320 may be provided to surround an upper end portion and an upper sidewall of the first conductive pillar 310.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

1. A semiconductor package, comprising:
a lower redistribution wiring layer having a first region and a second region, and including first redistribution wirings;
a semiconductor chip on the first region of the lower redistribution wiring layer and electrically connected to the first redistribution wirings;
a molding member covering the semiconductor chip on the lower redistribution wiring layer;
a plurality of vertical conductive structures penetrating the molding member on the second region of the lower redistribution wiring layer, each of the plurality of vertical conductive structures including a first conductive pillar on a bonding pad on the first redistribution wirings in the second region and a second conductive pillar stacked on the first conductive pillar; and
an upper redistribution wiring layer on the molding member and having second redistribution wirings electrically connected to the plurality of vertical conductive structures,
wherein the second redistribution wirings include,
a first upper redistribution wiring extending from an end portion of the second conductive pillar on an upper molding member; and
a second upper redistribution wiring stacked on the first upper redistribution wiring.

2. The semiconductor package of claim 1, wherein each of the first conductive pillars has a first length and each of the second conductive pillars has a second length greater than the first length.

3. The semiconductor package of claim 2, wherein the first length is in a range of 50 μm to 100 μm, and the second length is in a range of 200 μm to 300 μm.

4. The semiconductor package of claim 2, wherein the second length of the second conductive pillar is at least twice the first length of the first conductive pillar.

5. The semiconductor package of claim 1, wherein each of the first conductive pillars has a first diameter and each of the second conductive pillars has a second diameter different from the first diameter.

6. The semiconductor package of claim 1, wherein the upper redistribution wiring layer further includes a heat dissipation pattern on a backside surface of the semiconductor chip.

7. The semiconductor package of claim 6, wherein the first upper redistribution wiring and the heat dissipation pattern include a same metal material.

8. The semiconductor package of claim 6, wherein the heat dissipation pattern directly contacts the backside surface of the semiconductor chip.

9. The semiconductor package of claim 1, wherein the semiconductor chip is arranged such that a front surface on which chip pads are arranged faces the lower redistribution wiring layer, and the semiconductor chip is mounted on the lower redistribution wiring layer via conductive bumps that are on the chip pads.

10. The semiconductor package of claim 1, further comprising:
a second package on the upper redistribution wiring layer,
wherein the second package includes a package substrate and at least one second semiconductor chip stacked on the package substrate.

11. A semiconductor package, comprising:
a lower redistribution wiring layer having a first region and a second region surrounding the first region, the lower redistribution wiring layer including first redistribution wirings;
a plurality of first and second bonding pads on an uppermost redistribution wirings of the first redistribution wirings on an upper surface of the lower redistribution wiring layer, the plurality of first bonding pads arranged in the first region, the plurality of second bonding pads arranged in the second region;
a semiconductor chip mounted on the first region of the lower redistribution wiring layer such that a front surface on which chip pads are arranged faces the lower redistribution wiring layer, the semiconductor chip electrically connected to the first redistribution wirings;
a molding member covering the semiconductor chip on the lower redistribution wiring layer;
a plurality of vertical conductive structures penetrating the molding member on the second region of the lower redistribution wiring layer, the plurality of vertical conductive structures including first conductive pillars on the plurality of second bonding pads and second conductive pillars stacked on the first conductive pillars respectively; and
an upper redistribution wiring layer on the molding member, having second redistribution wirings electrically connected to the plurality of vertical conductive structures, and a heat dissipation pattern on a backside surface of the semiconductor chip.

12. The semiconductor package of claim 11, wherein the semiconductor chip is mounted on the lower redistribution wiring layer via conductive bumps that are on the chip pads.

13. The semiconductor package of claim 12, wherein the conductive bumps are on the plurality of first bonding pads respectively.

14. The semiconductor package of claim 11, wherein each of the first conductive pillars has a first length and each of the second conductive pillars has a second length greater than the first length.

15. The semiconductor package according to claim 14, wherein the first length is in a range of 50 μm to 100 μm, and the second length is in a range of 200 μm to 300 μm.

16. The semiconductor package of claim 14, wherein the second length of the second conductive pillar is at least twice the first length of the first conductive pillar.

17. The semiconductor package of claim 11, wherein the second redistribution wirings includes:
a first upper redistribution wiring extending from an end portion of the second conductive pillar on an upper molding member; and
a second upper redistribution wiring stacked on the first upper redistribution wiring.

18. The semiconductor package of claim 17, wherein an upper surface of the first upper redistribution wiring is located on a same plane as an upper surface of the heat dissipation pattern.

19. The semiconductor package of claim 11, wherein the heat dissipation pattern directly contacts the backside surface of the semiconductor chip.

20. A semiconductor package, comprising:
a lower redistribution wiring layer having a first region and a second region surrounding the first region, the lower redistribution wiring layer including first redistribution wirings;
a semiconductor chip on the first region of the lower redistribution wiring layer such that a front surface on which chip pads are arranged faces the lower redistribution wiring layer;
a molding member covering the semiconductor chip on the lower redistribution wiring layer;
a plurality of vertical conductive structures penetrating the molding member on the second region of the lower redistribution wiring layer, the plurality of vertical conductive structures electrically connected to the first redistribution wirings, each of the plurality of vertical conductive structures including a first conductive pillar and a second conductive pillar stacked on the first conductive pillar; and
an upper redistribution wiring layer on the molding member, having second redistribution wirings electrically connected to the plurality of vertical conductive structures, and a heat dissipation pattern on a backside surface of the semiconductor chip,
wherein each of the first conductive pillars has a first length and each of the second conductive pillars has a second length greater than the first length.

21.-30. (canceled)
